(19) United States
(12) Patent Application Publication
(10) Pub. No.: US 2026/0271466 A1
(43) Pub. Date: Sep. 10, 2026

(54) LIGHT-EMITTING MODULE

(71) Applicant: NICHIA CORPORATION, Anan-shi (JP)

(72) Inventor: Tetsuya TOMINAGA, Komatsushima-shi (JP)

(73) Assignee: NICHIA CORPORATION, Anan-shi (JP)

(21) Appl. No.: 19/548,133

(22) Filed: Feb. 24, 2026

(30) Foreign Application Priority Data
Mar. 6, 2025 (JP) 2025-035721

(51) Int. Cl. H10H 29/855; H10H 29/14; H10H 29/856

(52) U.S. Cl. CPC H10H 29/855; H10H 29/142; H10H 29/856

(57) ABSTRACT

A light-emitting module includes a light source including a first light-emitting unit that emits light with a first chromaticity and a second light-emitting unit that emits light with a second chromaticity different from the first chromaticity; and a lens having a light incident surface and a light exiting surface and including, at the light incident surface, a first protrusion having an annular shape, the first protrusion having a first light reflective surface. The light incident surface of the lens faces the light source, and the first light-emitting unit and the second light-emitting unit are located inward of the first light reflective surface of the first protrusion in a top view.

### CROSS-REFERENCE TO RELATED APPLICATION

This application claims priority to Japanese Patent Application No. 2025-035721, filed on Mar. 6, 2025, the disclosure of which is hereby incorporated by reference in its entirety.

### TECHNICAL FIELD

The present disclosure relates to a light-emitting module.

### BACKGROUND

Light-emitting modules including semiconductor elements such as light-emitting diodes (LEDs) and an optical member such as a lens have been widely used. As an example of such a light-emitting module, for example, Japanese Patent Publication No. 2013-134898 discloses an illumination device including a light source that has a plurality of light-emitting regions and can control the plurality of light-emitting regions to different light-emitting states from one another, and an optical member having a plurality of light exiting portions facing the respective light-emitting regions of the light source and configured to emit output light beams from the respective light-emitting regions in different directions from one another. In the illumination device, a plurality of light-emitting elements having different color temperatures for each light-emitting region are two-dimensionally arranged in each of the plurality of light-emitting regions.

### SUMMARY

An object of an embodiment according to the present disclosure is to provide a light-emitting module in which color adjustment is possible.

A light-emitting module according to an embodiment of the present disclosure includes: a light source including a first light-emitting unit configured to emit light with a first chromaticity and a second light-emitting unit configured to emit light with a second chromaticity different from the first chromaticity; and a lens having a light incident surface and a light exiting surface and including a first protrusion having an annular shape on the light incident surface, the first protrusion having a first light reflective surface. The light incident surface of the lens faces the light source, and the first light-emitting unit and the second light-emitting unit are located inward of the first light reflective surface of the first protrusion in a top view.

An embodiment of the present disclosure can provide a light-emitting module in which color adjustment is possible.

### BRIEF DESCRIPTION OF DRAWINGS

FIG. 1 is a schematic top view of a light-emitting module according to a first embodiment.

FIG. 2 is a schematic cross-sectional view taken along line II-II in FIG. 1.

FIG. 3 is a schematic top view illustrating a first example of a light source included in the light-emitting module according to the first embodiment.

FIG. 4 is a schematic cross-sectional view taken along line IV-IV in FIG. 3.

FIG. 5 is a schematic top view illustrating a second example of the light source included in the light-emitting module according to the first embodiment.

FIG. 6 is a schematic cross-sectional view taken along line VI-VI in FIG. 5.

FIG. 7 is a schematic diagram illustrating the behavior of light emitted from each of a first light-emitting unit and a second light-emitting unit of the light source included in the light-emitting module according to the first embodiment.

FIG. 8 is a schematic diagram illustrating the behavior of light emitted from a third light-emitting unit of the light source included in the light-emitting module according to the first embodiment.

FIG. 9 is a schematic diagram illustrating illuminance on an irradiation plane when only the first light-emitting unit and the second light-emitting unit of the light source included in the light-emitting module according to the first embodiment are caused to emit light.

FIG. 10 is a schematic diagram illustrating illuminance on an irradiation plane when all light-emitting units in the light source included in the light-emitting module according to the first embodiment are caused to emit light.

FIG. 11 is a schematic diagram for illustrating a distance from an optical axis to an annular first protrusion in a lens included in the light-emitting module according to the first embodiment.

FIG. 12 is a diagram illustrating an example of a relationship between a distance from the optical axis to the annular first protrusion in the lens included in the light-emitting module according to the first embodiment and optical characteristics.

FIG. 13 is a diagram illustrating an example of a relationship between the shapes of the annular first protrusion and an inner region in the lens included in the light-emitting module according to the first embodiment and optical characteristics.

FIG. 14 is a schematic diagram for illustrating an irradiation angle of light emitted from the light source.

FIG. 15 is a schematic top view of a light-emitting module according to a modified example of the first embodiment.

FIG. 16 is a schematic cross-sectional view taken along line XVI-XVI in FIG. 15.

FIG. 17 is a diagram illustrating an example of color unevenness when a light emission pattern of a light source included in the light-emitting module according to the modified example of the first embodiment.

FIG. 18 is a schematic top view of a light-emitting module according to a second embodiment.

FIG. 19 is a schematic cross-sectional view taken along line XIX-XIX in FIG. 18.

### DETAILED DESCRIPTION

Light-emitting modules according to embodiments of the present disclosure are described in detail with reference to the drawings. However, the following embodiments are examples of light-emitting modules to embody the technical concepts of the present invention, and the present invention is not limited to the embodiments described below. The dimensions, materials, shapes, relative arrangements, and the like of components described in the embodiments are not intended to limit the scope of the present invention, but are merely illustrative examples, unless otherwise specifically stated. The sizes, positional relationship, or the like of members illustrated in the drawings may be exaggerated for clarity of description. In the following description, members having the same names and reference signs represent the same or similar members, and a detailed description of these members is omitted as appropriate. As a cross-sectional view, an end view illustrating only a cut surface may be used.

In the following drawings, directions may be indicated by an X-axis, a Y-axis, and a Z-axis. The X-axis, the Y-axis, and the Z-axis are directions orthogonal to each other. An X direction along the X-axis and a Y direction along the Y-axis indicate directions along a light-emitting surface of a light-emitting unit in a light source included in the light-emitting module according to the embodiment. A Z direction along the Z-axis indicates a direction orthogonal to the light-emitting surface. That is, the light-emitting surface of the light-emitting unit is parallel to an XY plane, and the Z-axis is orthogonal to the XY plane.

The direction in which the arrow points in the X direction is denoted as a +X side, and the opposite side to the +X side is denoted as a −X side. The direction in which the arrow points in the Y direction is denoted as a +Y side, and the opposite side to the +Y side is denoted as a −Y side. The direction in which the arrow points in the Z direction is denoted as a +Z side, and the opposite side to the +Z side is denoted as a −Z side. In the embodiments, the light-emitting unit included in the light-emitting module emits light toward the +Z side as an example. However, these definitions do not limit the orientations of the light-emitting modules according to the embodiments when used, and the light-emitting modules according to the embodiments may be used in any orientation.

In the present description, a surface of an object as seen from the +Z side is referred to as an “upper surface,” and a surface of the object as seen from the −Z side is referred to as a “lower surface.” The +Z side as seen from the object may be referred to as an “upper side,” and the −Z side as seen from the object may be referred to as a “lower side.” In the following embodiments, the expression “along the X-axis, the Y-axis, and the Z-axis” includes the case in which an object has an inclination within a range of ±10° relative to these axes. In the present description, “orthogonal” may include a tolerance within ±10° with respect to 90°. In the present description, “along” may include a tolerance within ±10° with respect to 0°. In addition, the expression “disposed on” includes not only a case in which two objects are in direct contact with each other but also a case of indirectly disposing, for example, disposing one object on another object with another member provided therebetween. The term “thickness” indicates a length of the object in the Z direction unless otherwise specifically stated.

In the present description or the claims, when a plurality of one type of constituent components are provided and these constituent components are to be denoted individually, the constituent components may be distinguished by adding terms such as “first,” “second,” and the like in front of the terms of the constituent components. Objects to be distinguished may differ between the present description and the claims.

### First Embodiment

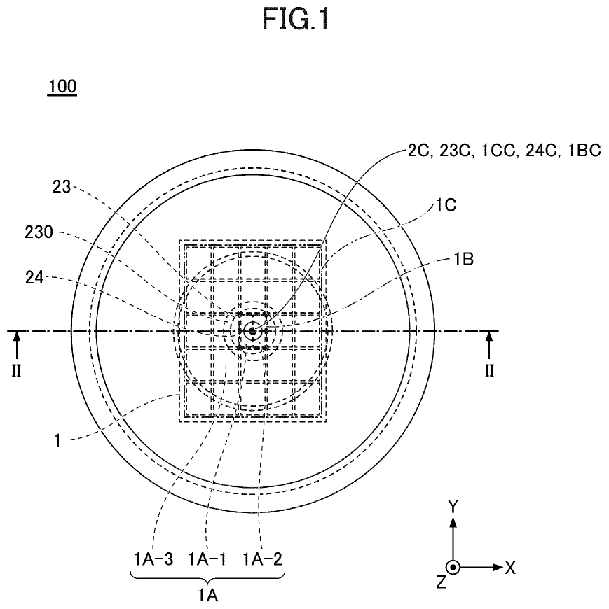

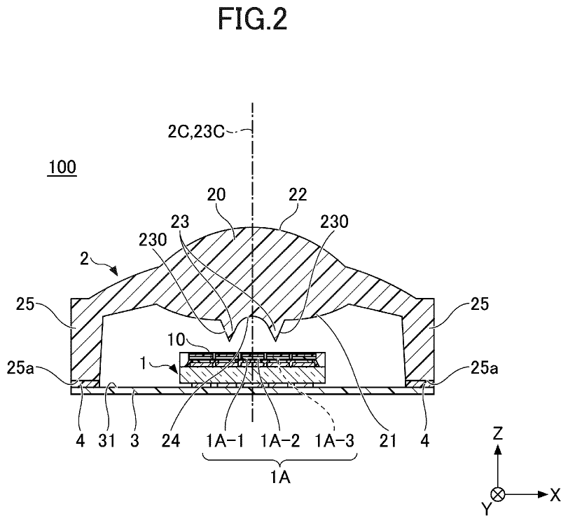

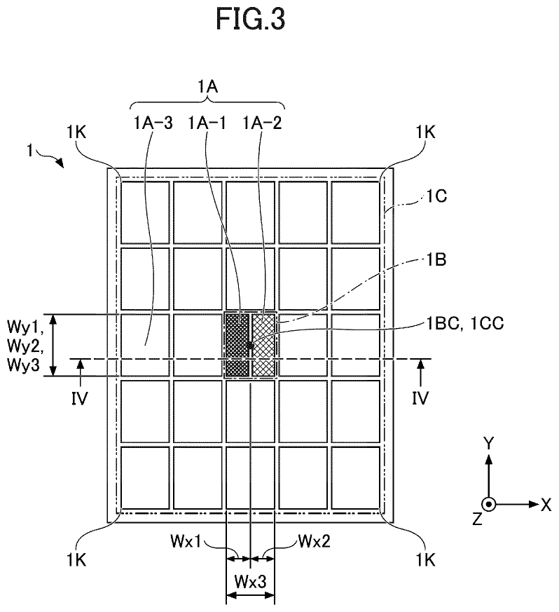

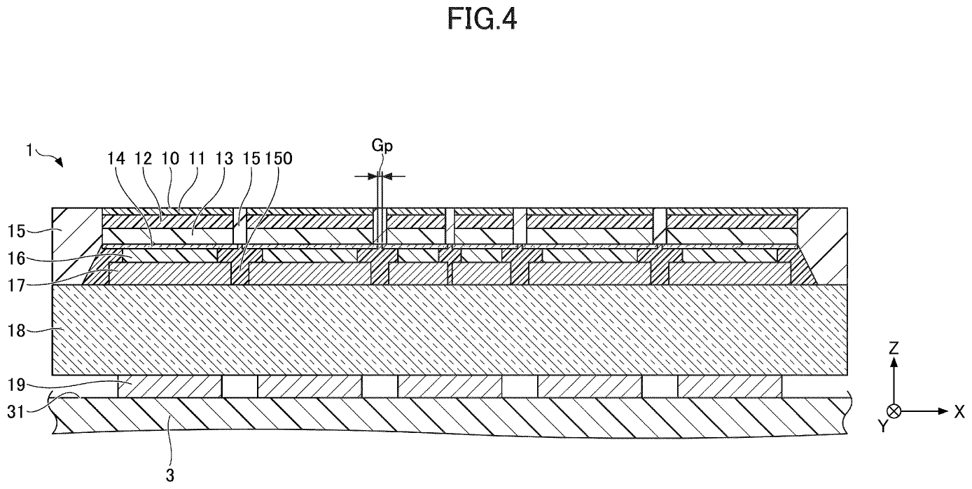

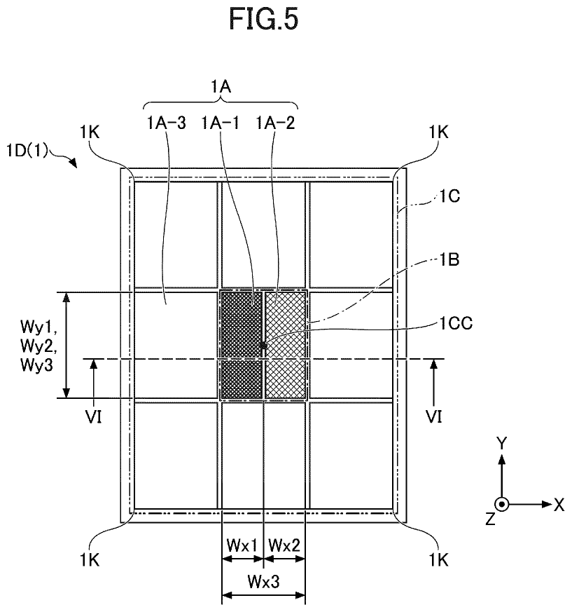

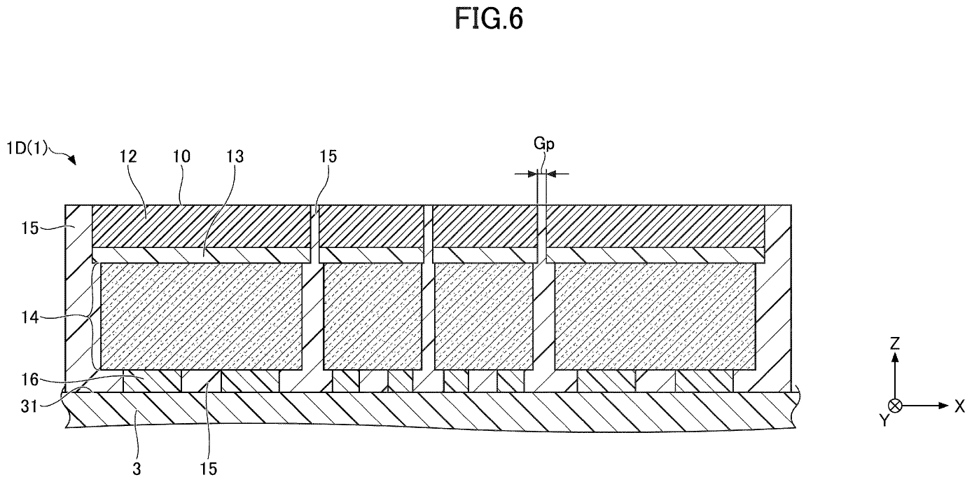

Configuration of Light-emitting Module according to First Embodiment A configuration of a light-emitting module according to a first embodiment is described with reference to FIGS. 1 to 6. FIG. 1 is a schematic top view of a light-emitting module 100 according to the first embodiment. FIG. 2 is a schematic cross-sectional view taken along line II-II in FIG. 1. FIG. 3 is a schematic top view illustrating a first example of a configuration of a light source 1 included in the light-emitting module 100. FIG. 4 is a schematic cross-sectional view taken along line IV-IV in FIG. 3. FIG. 5 is a schematic top view illustrating a second example of the configuration of the light source 1 included in the light-emitting module 100. FIG. 6 is a schematic cross-sectional view taken along line VI-VI in FIG. 5.

The light-emitting module 100 is, as an example, a light source device for a flash of an imaging device mounted in a smartphone, or a light source device used in a flashlight/torch function and the like of a smartphone. Examples of the imaging device include a camera for imaging a still image and a video camera for imaging a moving image.

As illustrated in FIGS. 1 and 2, the light-emitting module 100 includes a light source 1 including a first light-emitting unit 1A-1 that emits light with a first chromaticity and a second light-emitting unit 1A-2 that emits light with a second chromaticity different from the first chromaticity. The light-emitting module 100 also includes a lens 2 having a light incident surface 21 and a light exiting surface 22 and including an annular first protrusion 23 having a first light reflective surface 230 on the light incident surface 21.

In the example illustrated in FIGS. 1 and 2, the light-emitting module 100 further includes a substrate 3 on which the light source 1 and the lens 2 are disposed, and a first adhesive member 4. The lens 2 is bonded to an upper surface 31 of the substrate 3 by the first adhesive member 4. The light source 1 further includes a plurality of third light-emitting units 1A-3 that each emit light with a third chromaticity different from the first chromaticity and the second chromaticity. In the example illustrated in FIGS. 1 and 2, the color temperature of light with the first chromaticity is higher than the color temperature of light with the second chromaticity, and the color temperature of light with the third chromaticity is in a range between the color temperature of light with the first chromaticity and the color temperature of light with the second chromaticity. The color temperature of light with the first chromaticity and the color temperature of light with the second chromaticity are in a range of 2500 K to 6500 K. In the present embodiment, the color temperature of light with the first chromaticity, the color temperature of light with the second chromaticity, and the color temperature of light with the third chromaticity are in a range of duv+0.0010 to duv+0.015. When the color temperature of light with the first chromaticity, the color temperature of light with the second chromaticity, and the color temperature of light with the third chromaticity are above (on the duv+side of) a blackbody locus, because the color of light beams approach green on a chromaticity diagram, light emitted by the light-emitting module 100 is more likely to be perceived as bright in photopic vision.

In the example illustrated in FIG. 1, an outer shape of the light-emitting module 100 is substantially circular in a top view. In a top view, an outer shape of the lens 2 is the outer shape of the light-emitting module 100. In the example illustrated in FIG. 1, the outer shape of the lens 2 is substantially circular in a top view. However, the outer shapes of the light-emitting module 100 and the lens 2 are not limited to substantially circular shapes in a top view and may have other shapes such as substantially elliptical shapes, substantially rectangular shapes, or substantially polygonal shapes.

The light source 1 is mounted on the upper surface 31 of the substrate 3. In the example illustrated in FIG. 1, the light source 1 has a substantially rectangular outer shape in a top view. The light source 1 includes a plurality of light-emitting units. In the example illustrated in FIG. 1, the light source 1 includes 26 light-emitting units 1A each having a substantially rectangular light-emitting surface 10. The 26 light-emitting units 1A include the first light-emitting unit 1A-1, the second light-emitting unit 1A-2, and the third light-emitting units 1A-3.

In a top view, the first light-emitting unit 1A-1 and the second light-emitting unit 1A-2 are located at a central portion 1B of the light source 1. In a top view, it can be said that the first light-emitting unit 1A-1 and the second light-emitting unit 1A-2 are line-symmetric with respect to the Y-axis and are point-symmetric with respect to a center 1BC of the central portion 1B of the light source 1. In a top view, the central portion 1B is a portion overlapping a center 1CC of a light-emitting region 1C. The light-emitting region 1C corresponds to a region including the light-emitting surface 10. When the light source 1 includes a plurality of the light-emitting surfaces 10, the light-emitting region 1C is a region connecting outer edges of the light-emitting surfaces 10 located on the outer side in a top view. In the example illustrated in FIG. 1, one first light-emitting unit 1A-1 and one second light-emitting unit 1A-2 are arranged at the central portion 1B in the X direction. However, as long as the central portion 1B includes at least one first light-emitting unit 1A-1 and at least one second light-emitting unit 1A-2, the light source 1 may include at least one of a plurality of first light-emitting units 1A-1 and a plurality of second light-emitting units 1A-2. At least one of the plurality of first light-emitting units 1A-1 and the plurality of second light-emitting units 1A-2 may be disposed in a matrix.

In a top view, the plurality of third light-emitting units 1A-3 are located around the central portion 1B of the light source 1. The first light-emitting unit 1A-1, the second light-emitting unit 1A-2, and the third light-emitting units 1A-3 are integrally formed. The expression “integrally” refers to a state in which the components are integrated into one and are inseparable. In the example illustrated in FIG. 1, the 26 light-emitting units 1A include 24 third light-emitting units 1A-3 disposed in an outer peripheral region to surround the entire periphery of the central portion 1B. The 24 third light-emitting units 1A-3 are disposed around the central portion 1B in a matrix. In other words, the plurality of third light-emitting units 1A-3 are located around the central portion 1B of the light source 1.

From another viewpoint, m and n are positive integers different from each other, and the light source 1 includes a plurality of light-emitting units 1A of m rows×m columns as a whole or m rows×n columns as a whole. In a top view, the plurality of light-emitting units 1A include one or more first light-emitting units 1A-1 and one or more second light-emitting units 1A-2 in the central portion 1B of the light source 1. In the example illustrated in FIG. 1, m=5, and the light source 1 has 26 (=5×5+1) light-emitting units 1A. In a top view, the 26 light-emitting units 1A include one first light-emitting unit 1A-1 and one second light-emitting unit 1A-2 at the central portion 1B of the light source 1.

The light-emitting surface 10 refers to a main light extraction surface of the light-emitting unit 1A. Accordingly, the light-emitting surface 10 of the light-emitting unit 1A also serves as a light-emitting surface of the light source 1. In the first example of the light source 1 illustrated in FIG. 3, the light-emitting region 1C includes 26 light-emitting surfaces 10. The shape of the outer edge of the light-emitting region 1C is a substantially rectangular shape in a top view. The light-emitting region 1C includes four corner portions 1K. Note that the number of the light-emitting units 1A included in the light source 1 is not limited to 26. As illustrated in FIG. 5 as a second example of the light-emitting unit 1A included in the light source 1, a light-emitting unit 1D includes at least the first light-emitting unit 1A-1 and the second light-emitting unit 1A-2 located at the central portion 1B, and eight third light-emitting units 1A-3 located around the central portion 1B. The light source 1 is not limited to a rectangular shape in a top view, and may have another shape such as a substantially circular shape, a substantially elliptical shape, or a substantially polygonal shape.

In the present embodiment, the light incident surface 21 of the lens 2 faces the light source 1, and the first light-emitting unit 1A-1 and the second light-emitting unit 1A-2 are located inward of the first light reflective surface 230 of the first protrusion 23 in a top view. In the example illustrated in FIG. 2, the lens 2 has a light-transmissive portion 20 and a first support portion 25. The light-transmissive portion 20 has the light incident surface 21 and the light exiting surface 22. The first support portion 25 supports the light-transmissive portion 20. The first support portion 25 is bonded to the upper surface 31 of the substrate 3 by the first adhesive member 4 disposed between a lower surface 25a of the first support portion 25 and the upper surface 31 of the substrate 3. In the example illustrated in FIG. 1, the center 1CC of the light-emitting region 1C overlaps an optical axis 2C of the lens 2 in a top view. The light source 1 emits light from the light-emitting surface 10 included in each of the plurality of light-emitting units 1A in a direction in which the light incident surface 21 of the lens 2 is located.

In the example illustrated in FIG. 2, the lens 2 is a biconvex lens. The light incident surface 21 includes a convex surface that is convex toward the light source 1, and the light exiting surface 22 includes a convex surface that is convex toward a location opposite to the light source 1. An inner region 24 of the light incident surface 21 surrounded by the first protrusion 23 is a concave surface that is recessed in a direction opposite to the direction in which the light source 1 is located. The annular first protrusion 23 and the first light reflective surface 230 of the lens 2 each have a circular annular shape centered on the optical axis 2C of the lens 2 in a top view.

In the example illustrated in FIG. 1, the optical axis 2C of the lens 2, a center 24C of the inner region 24 surrounded by the first protrusion 23, and the center 1CC of the light-emitting region 1C of the light source 1 overlap one another in a top view. The center 24C of the inner region 24 surrounded by the first protrusion 23 is, namely, a central axis 23C of the first protrusion 23. The center 24C of the inner region 24 surrounded by the first protrusion 23 overlaps the center 1BC of the central portion 1B of the light source 1 in a top view. The optical axis 2C, the central axis 23C, the center 1CC of the light-emitting region 1C, the center 24C of the inner region 24, and the center 1BC of the central portion 1B overlap one another. Therefore, in FIG. 1, the reference signs of the optical axis 2C, the central axis 23C, the center 1CC of the light-emitting region 1C, the center 24C of the inner region 24, and the center 1BC of the central portion 1B are indicated together. Also in the following drawings, reference signs may be indicated together for the same or similar purpose.

The first light-emitting unit 1A-1, the second light-emitting unit 1A-2, and the 24 third light-emitting units 1A-3 are individually drivable. That is, the light source 1 may drive the first light-emitting unit 1A-1, the second light-emitting unit 1A-2, and the 24 third light-emitting units 1A-3 individually or in units of a plurality of groups. When the light source 1 includes a plurality of first light-emitting units 1A-1, the plurality of first light-emitting units 1A-1 may be driven individually or in units of a plurality of groups. When the light source 1 includes a plurality of second light-emitting units 1A-2, the plurality of second light-emitting units 1A-2 may be driven individually or in units of a plurality of groups. Each of the first light-emitting unit 1A-1, the second light-emitting unit 1A-2, and the 24 third light-emitting units 1A-3 emits light toward the lens 2 provided above the light source 1.

In the light-emitting module 100, a light distribution of light emitted from the light-emitting module 100 can be controlled by controlling a distribution of current supplied to each of the first light-emitting unit 1A-1, the second light-emitting unit 1A-2, and the 24 third light-emitting units 1A-3.

The light-emitting module 100 turns on the first light-emitting unit 1A-1, the second light-emitting unit 1A-2, and the 24 third light-emitting units 1A-3 individually or in units of groups at a desired brightness. This can increase the contrast of irradiation light on the irradiation plane irradiated with the light from the light source 1. In addition, the light-emitting module 100 can partially irradiate the irradiation plane by turning on the first light-emitting unit 1A-1, the second light-emitting unit 1A-2, and the 24 third light-emitting units 1A-3 individually or in units of groups. The expression “partially irradiate” refers to irradiating a part of the region of the irradiation plane with light.

When the light-emitting module 100 is used as a light source device for a flash of an imaging device, for example, light to be emitted from the light-emitting module 100 can be switched between a wide-angle mode and a narrow-angle mode. The wide-angle mode is a mode in which only a part of the third light-emitting units 1A-3 emits light, a mode in which all of the third light-emitting units 1A-3 emit light and the first light-emitting unit 1A-1 and the second light-emitting unit 1A-2 emit no light, or a mode in which all of the third light-emitting units 1A-3, the first light-emitting unit 1A-1, and the second light-emitting unit 1A-2 emit light. The emitted light from the light-emitting module 100 in the wide-angle mode has a wide-angle light distribution. In addition, the light-emitting module 100 can emit the wide-angle light distribution and an super-wide-angle light distribution that is a light distribution wider than the wide-angle light distribution by adjusting the intensity of light of each of the first light-emitting unit 1A-1, the second light-emitting unit 1A-2, and the 24 third light-emitting units 1A-3. In the following description, the wide-angle light distribution and the super-wide-angle light distribution may be collectively referred to as the wide-angle light distribution or the wide-angle mode. The narrow-angle mode is a mode in which a part of the third light-emitting units 1A-3, the first light-emitting unit 1A-1, and the second light-emitting unit 1A-2 emit light, or a mode in which the third light-emitting units 1A-3 emit no light and the first light-emitting unit 1A-1 and the second light-emitting unit 1A-2 emit light. The light emitted from the light-emitting module 100 in the narrow-angle mode has a narrow-angle light distribution. That is, the light distribution angle in the narrow-angle mode is smaller than the light distribution angle in the wide-angle mode.

Because the light-emitting module 100 can switch irradiation light according to the wide-angle mode and the narrow-angle mode, for example, imaging according to a imaging mode such as close-up or telephoto can be performed with an imaging device by using light emitted from the light-emitting module 100. In addition, when the light-emitting module 100 is used as a light source device for a flashlight/torch of a smartphone, light emitted from the light-emitting module 100 is set to the narrow-angle mode, so that the irradiation light can reach a long distance and the performance of the flashlight/torch can be enhanced.

The light-emitting module 100 illustrated in FIGS. 1 and 2 can change the light emission output of each of the first light-emitting unit 1A-1 and the second light-emitting unit 1A-2 based on the output of an outside air temperature sensor. Accordingly, when the light emission output of the first light-emitting unit 1A-1 is larger than the light emission output of the second light-emitting unit 1A-2, outside air temperature sensors of the first light-emitting unit 1A-1 and the second light-emitting unit 1A-2 may be included in the light-emitting module 100, or may be included in an equipment or a device provided outside the light-emitting module 100.

In the present embodiment, the first light-emitting unit 1A-1 and the second light-emitting unit 1A-2 are located inward of the first light reflective surface 230 of the first protrusion 23 in a top view. Light with the first chromaticity emitted from the first light-emitting unit 1A-1 and reflected by the first light reflective surface 230 of the first protrusion 23 and light with the second chromaticity emitted from the second light-emitting unit 1A-2 and reflected by the first light reflective surface 230 of the first protrusion 23 overlap and are mixed on an irradiation plane. Specifically, in the case of using, as a reference, the color of mixed-color light when the light emission output of the first light-emitting unit 1A-1 and the light emission output of the second light-emitting unit 1A-2 are the same, the color of the mixed-color light is bluish when the light emission output of the first light-emitting unit 1A-1 is larger than the light emission output of the second light-emitting unit 1A-2, and the color of the mixed-color light is reddish when the light emission output of the first light-emitting unit 1A-1 is smaller than the light emission output of the second light-emitting unit 1A-2. In this way, the present embodiment can provide the light-emitting module 100 in which color adjustment is possible. In addition, the color temperature of light emitted by the light-emitting module 100 can be adjusted according to an outside air temperature. For example, the light-emitting module 100 can emit reddish mixed-color light when the outside air temperature is low, and can emit bluish mixed-color light when the outside air temperature is high. Moreover, the light-emitting module 100 may change the light emission output of each of the first light-emitting unit 1A-1 and the second light-emitting unit 1A-2 based on the color temperature of external light or ambient light. For example, the light-emitting module 100 can emit bluish white light when the color temperature of the external light or the ambient light is equal to or higher than 5000 K such as the color temperature of sunlight in the daytime, and emit reddish yellow (amber) light when the color temperature of the external light or the ambient light is equal to or lower than 3300 K such as the color temperature of sunlight in the evening. In addition, even when the color temperature of the external light or the ambient light is about 3500 K such as the color temperature of sunlight before sunrise, the color temperature of light emitted from the light-emitting module 100 can be adjusted by changing the light emission output of each of the first light-emitting unit 1A-1 and the second light-emitting unit 1A-2. In the present description, the ambient light includes light entering the inside of the light-emitting module 100.

The light source 1 includes the 24 third light-emitting units 1A-3 that each emit light with the third chromaticity different from the first chromaticity and the second chromaticity. In a top view, the first light-emitting unit 1A-1 and the second light-emitting unit 1A-2 are located at the central portion 1B, and the 24 third light-emitting units 1A-3 are located around the central portion 1B. The first light-emitting unit 1A-1, the second light-emitting unit 1A-2, and the third light-emitting units 1A-3 are integrally formed. With this configuration, the light-emitting module 100 can emit mixed-color light of light with the first chromaticity and light with the second chromaticity, and can emit light with the third chromaticity.

The color temperature of light with the third chromaticity is preferably in a range between the color temperature of light with the first chromaticity and the color temperature of light with the second chromaticity. This can allow the color temperature of the mixed-color light of light with the first chromaticity and light with the second chromaticity to be equal to the color temperature of light with the third chromaticity. The lens 2 is a biconvex lens. This can allow light with the first chromaticity and light with the second chromaticity reflected by the first light reflective surface 230 of the first protrusion 23 to be converged and controlled to travel toward the optical axis 2C of the lens 2 in a top view.

In the present embodiment, the inner region 24 of the light incident surface 21 surrounded by the first protrusion 23 is a concave surface that is recessed in the direction opposite to the direction in which the light source 1 is located. Because the inner region 24 is a concave surface, light with the first chromaticity and light with the second chromaticity entering the inside of the lens 2 through the inner region 24 diverge due to the negative refractive power of the lens 2, so that the light with the first chromaticity and the light with the second chromaticity overlap and are mixed. This can reduce color unevenness in irradiation light of the light-emitting module 100. The inner region 24 may be a convex surface that is convex in the direction in which the light source 1 is located.

The optical axis 2C of the lens 2 preferably overlaps the center 24C of the inner region 24 surrounded by the first protrusion 23 in a top view. This can control light emitted from the light source 1 and incident on the inner region 24 with reference to the optical axis 2C of the lens 2, thereby facilitating the control of the light. The center 24C of the inner region 24 preferably overlaps the center 1BC of the central portion 1B of the light source 1 in a top view. This can control each of light with the first chromaticity and light with the second chromaticity emitted from the light source 1 with reference to the optical axis 2C of the lens 2, thereby facilitating the control of the light with the first chromaticity and the light with the second chromaticity. As a result, color adjustment control by color mixing of the first chromaticity and the second chromaticity is facilitated.

The light source 1 preferably includes a plurality of light-emitting units 1A of m rows×m columns as a whole or m rows×n columns as a whole, and the plurality of light-emitting units 1A preferably include one or more first light-emitting units 1A-1 and one or more second light-emitting units 1A-2 in the central portion 1B of the light source 1 in a top view. By including the first light-emitting unit 1A-1 and the second light-emitting unit 1A-2 in the central portion 1B, light with the first chromaticity from the first light-emitting unit 1A-1 and light with the second chromaticity from the second light-emitting unit 1A-2 are likely to overlap. This can reduce color unevenness in the color adjustment of the first chromaticity and the second chromaticity.

Each component of the light-emitting module 100 is described in detail below.

### First Example of Light Source 1

The first example of the light source 1 is described in detail with reference to FIGS. 3 and 4. The light source 1 according to the present embodiment includes the light-emitting unit 1A including the first light-emitting unit 1A-1 and the second light-emitting unit 1A-2, and a base body 18. The base body 18 includes a first wiring member 17 on an upper surface thereof and a second wiring member 19 on a lower surface thereof. The light source 1 includes one first light-emitting unit 1A-1, one second light-emitting unit 1A-2, and 24 third light-emitting units 1A-3. The first light-emitting unit 1A-1 and the second light-emitting unit 1A-2 are arranged side by side in the X direction at the central portion 1B of the light source 1, in a top view.

The third light-emitting units 1A-3 are disposed vertically, laterally, or in a matrix in a top view. For easy understanding, when an area occupied by one first light-emitting unit 1A-1 and one second light-emitting unit 1A-2 is equal to an area occupied by one third light-emitting unit 1A-3 in a top view, the example illustrated in FIG. 3 can be regarded as a 5×5 matrix as a whole. In this case, five third light-emitting units 1A-3 are aligned in each of first, second, fourth, and fifth rows in the X direction. In addition, five third light-emitting units 1A-3 are aligned in each of first, second, fourth, and fifth columns in the Y direction. The central portion 1B is located at a position corresponding to the third row and the third column in the 5×5 matrix. In the following description, the example of the arrangement of the light-emitting units 1A illustrated in FIG. 3 may be regarded as a 5×5 matrix as a whole.

A width Wx1 is a width of the first light-emitting unit 1A-1 in the X direction. A width Wx2 is a width of the second light-emitting unit 1A-2 in the X direction. A width Wx3 is a width of the third light-emitting unit 1A-3 in the X direction. A width Wy1 is a width of the first light-emitting unit 1A-1 in the Y direction. A width Wy2 is a width of the second light-emitting unit 1A-2 in the Y direction. A width Wy3 is a width of the third light-emitting unit 1A-3 in the Y direction. In the example illustrated in FIG. 3, the width Wx1 and the width Wx2 are substantially equal to each other. The width Wx3 is twice as wide as the width Wx1. The width Wy1, the width Wy2, and the width Wy3 are equal to one another.

Note that in FIG. 3, to distinguish the first light-emitting unit 1A-1, the second light-emitting unit 1A-2, and the third light-emitting unit 1A-3 from one another, the third light-emitting unit 1A-3 is represented by white, and the first light-emitting unit 1A-1 and the second light-emitting unit 1A-2 are represented by different dot patterns. In addition, in FIG. 3, to avoid complication of the drawing, only the third light-emitting unit 1A-3 disposed in the third row and the first column among the 24 third light-emitting units 1A-3 is denoted by a reference sign.

The light source 1 includes, on its upper surface, the light-emitting surface 10 of the light-emitting unit 1A, and is disposed on the upper surface 31 of the substrate 3, for example, on a surface of the substrate 3 on the +Z side with a surface of the light source 1 opposite to the light-emitting surface 10 as a mounting surface. The first light-emitting unit 1A-1, the second light-emitting unit 1A-2, and the 24 third light-emitting units 1A-3 have substantially the same configuration except for dimensions in a top view. Therefore, in the following description, the configuration of the third light-emitting unit 1A-3 disposed in the third row and the first column may be described as a representative example.

In the example illustrated in FIG. 4, the third light-emitting unit 1A-3 includes a light-emitting element 14, a wavelength conversion member 13 disposed above the light-emitting element 14, a light diffusion member 12 disposed above the wavelength conversion member 13, and a first covering member 11 disposed above the light diffusion member 12. In addition, the third light-emitting unit 1A-3 includes a second covering member 15 covering the lateral surfaces of the first covering member 11, the light diffusion member 12, the wavelength conversion member 13, and the light-emitting element 14.

The light-emitting element 14 includes, on a surface opposite to a surface facing the wavelength conversion member 13, that is, on a lower surface thereof, at least a pair of positive and negative electrodes 16. The light-emitting element 14 is disposed on the base body 18 with the electrode 16 and the first wiring member 17 interposed therebetween. The lateral surfaces of each of the electrode 16 and the first wiring member 17, and the lateral surface and the lower surface of the light-emitting element 14 are covered with a resin member 150. The resin member 150 absorbs an external force applied to the light-emitting element 14 from the outside in the manufacturing process, and reduces the external force applied to the light-emitting element 14.

The base body 18 includes wirings on the surface or both on the surface and in the interior. The first wiring member 17 and the second wiring member 19 are wirings of the base body 18. The light source 1 and the substrate 3 are electrically connected by connecting the electrode 16 of the light-emitting element 14 and the wiring of the substrate 3 with a conductive member such as a bump and solder via the first wiring member 17, the base body 18, and the second wiring member 19. Note that the configuration, the size, and the like of the wiring of the substrate 3 are set according to the configuration and the size of the electrode 16 of the light-emitting element 14.

The second covering member 15 integrally holds a plurality of first covering members 11, a plurality of light diffusion members 12, and a plurality of wavelength conversion members 13. In the example illustrated in FIG. 4, the second covering member 15 is disposed on the lateral surfaces of the first covering member 11, the light diffusion member 12, and the wavelength conversion member 13. The second covering member 15 is disposed between adjacent first covering members 11, between adjacent light diffusion members 12, and between adjacent wavelength conversion members 13, respectively. The second covering member 15 integrally holds the first covering member 11, the light diffusion member 12, and the wavelength conversion member 13 included in each of the first light-emitting unit 1A-1, the second light-emitting unit 1A-2, and the 24 third light-emitting units 1A-3. An upper surface of the second covering member 15 constitutes a part of the upper surface of the light source 1. In addition, the second covering member 15 includes two long lateral surfaces and two short lateral surfaces, and the four lateral surfaces constitute a substantially rectangular outer shape of the light source 1 in a top view. With the second covering member 15 integrally holding the plurality of first covering members 11, the plurality of light diffusion members 12, and the plurality of wavelength conversion members 13, the light source 1 can be easily mounted.

The light source 1 includes the one first light-emitting unit 1A-1, the one second light-emitting unit 1A-2, and the 24 third light-emitting units 1A-3, resulting in an increase in the degree of freedom in the pattern of light that can be emitted from the light source 1. The second covering member 15 may be disposed on the lateral surfaces of the plurality of light-emitting elements 14. With the second covering member 15 integrally holding the plurality of light-emitting elements 14 and the plurality of wavelength conversion members 13, the light source 1 can be easily mounted.

The light-emitting element 14 includes various semiconductors including a group III-V compound semiconductor and a group II-VI compound semiconductor, and the like. As the semiconductor, a nitride-based semiconductor such as In_{X}Al_{Y}Ga_{1-X-Y}N (0≤X, 0≤Y, X+Y≤1) is preferably used, and InN, AlN, GaN, InGaN, AlGaN, InGaAlN, and the like can also be used. The light-emitting element 14 is an LED or a laser diode (LD), for example. The nitride-based semiconductor of the light-emitting element 14 is provided on a growth substrate such as sapphire. Note that the light-emitting element 14 may be obtained by forming a nitride-based semiconductor on the growth substrate and then removing the growth substrate. A light emission peak wavelength of the light-emitting element 14 is preferably in a range of 400 nm to 530 nm, more preferably in a range of 420 nm to 490 nm, even more preferably in a range of 450 nm to 475 nm from the viewpoints of light emission efficiency, excitation of a wavelength conversion substance to be described below, and the like.

The wavelength conversion member 13 is, for example, a member having a substantially rectangular shape in a top view. The wavelength conversion member 13 covers an upper surface of the light-emitting element 14. The wavelength conversion member 13 contains a wavelength conversion substance that converts a wavelength of at least a part of light from the light-emitting element 14. The wavelength conversion member 13 can be formed using a light-transmissive resin material or an inorganic material such as ceramic or glass. As the resin material, a thermosetting resin, such as a silicone resin, a silicone modified resin, an epoxy resin, an epoxy modified resin, or a phenol resin, can be used. Particularly, a silicone resin or a modified resin thereof with high light resistance and heat resistance is used. Note that light transmissivity here preferably refers to transmission of 60% or more of light from the light-emitting element 14. In addition, the wavelength conversion member 13 can use a thermoplastic resin such as a polycarbonate resin, an acrylic resin, a methyl pentene resin, or a polynorbornene resin. The wavelength conversion member 13 may be, for example, a member containing a wavelength conversion substance in a resin material, ceramic, glass, or the like, a sintered body of the wavelength conversion substance, or the like. Moreover, the wavelength conversion member 13 may contain a light diffusion substance to be described below in the above resin. In addition, the wavelength conversion member 13 may also be a multilayer in which a resin layer containing the wavelength conversion substance or the light diffusion substance is disposed on a surface of a molded body of resin, ceramic, glass, or the like on the ±Z side.

Examples of the wavelength conversion substance contained in the wavelength conversion member 13 that can be used include an yttrium aluminum garnet phosphor (for example, (Y,Gd)₃ (Al,Ga)₅O₁₂:Ce), a lutetium aluminum garnet phosphor (for example, Lu₃ (Al,Ga)₅O₁₂:Ce), a terbium aluminum garnet phosphor (for example, Tb₃ (Al,Ga)₅O₁₂:Ce), a CCA phosphor (for example, Ca₁₀ (PO₄)₆Cl₂:Eu), an SAE phosphor (for example, Sr₄Al₁₄O₂₅:Eu), a chlorosilicate phosphor (for example, Ca₈MgSi₄O₁₆Cl₂:Eu), a silicate phosphor (for example, (Ba, Sr, Ca,Mg)₂SiO₄:Eu), oxynitride phosphors such as a β-SiAlON phosphor (for example, (Si,Al)₃ (O,N)₄:Eu) or an α-SiAlON phosphor (for example, Ca(Si, Al)₁₂ (O,N)₁₆:Eu), nitride phosphors such as an LSN phosphor (for example, (La, Y)₃Si₆N₁₁:Ce), a BSESN phosphor (for example, (Ba,Sr)₂Si₅N₈:Eu), an SLA phosphor (for example, SrLiAl₃N₄:Eu), a CASN phosphor (for example, CaAlSiN₃:Eu), or an SCASN phosphor (for example, (Sr,Ca)AlSiN₃: Eu), fluoride phosphors such as a KSF phosphor (for example, K₂SiF₆:Mn), a KSAF phosphor (for example, K₂(Si₁₋ₓAlₓ)F₆₋ₓ:Mn, where x satisfies 0<x<1), or an MGF phosphor (for example, 3.5MgO·0.5MgF₂·GeO₂:Mn), a quantum dot having a perovskite structure (for example, (Cs,FA,MA) (Pb,Sn) (F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu) (In,Ga) (S,Se)₂), and the like.

The above wavelength conversion substance is in the form of particles. In addition, one of these types of wavelength conversion substance can be used alone, or two or more of these types of wavelength conversion substance can be used in combination.

The light-emitting unit 1A includes the light-emitting element 14 and the wavelength conversion member 13 and thus can emit mixed-color light including a color of light emitted from the light-emitting element 14 and a color of light emitted from the wavelength conversion member 13. In the light-emitting unit 1A, a degree of freedom in a color of light emitted from the light-emitting unit 1A can be increased by a combination of the light-emitting element 14 and the wavelength conversion member 13.

In the present embodiment, the light source 1 uses a blue LED as the light-emitting element 14, and the wavelength conversion member 13 contains a wavelength conversion substance that converts the wavelength of the light emitted from the light-emitting element 14 into yellow light. Thus, the light source 1 emits white light. The wavelength or chromaticity of light emitted from the light source 1 may be appropriately selected according to an application of the light-emitting module 100.

The light diffusion member 12 is a member that diffuses light beams from the light-emitting element 14 and the wavelength conversion member 13, and is, for example, a member having a substantially rectangular shape in a top view. As the light diffusion member 12, for example, a resin material containing a light diffusion substance can be used. Examples of the light diffusion substance included in the light diffusion member 12 include titanium oxide, barium titanate, aluminum oxide, and silicon oxide, and one of these substances can be used alone, or two or more of these substances can be used in combination. For the resin material, a resin material containing a thermosetting resin, such as an epoxy resin, an epoxy modified resin, a silicone resin, a silicone modified resin, or a phenol resin, as a main component is preferably used as a base material.

The second covering member 15 is a member that covers the lateral surfaces of the first covering member 11, the light diffusion member 12, the wavelength conversion member 13, and the light-emitting element 14. The second covering member 15 directly or indirectly covers the lateral surfaces of the first covering member 11, the light diffusion member 12, the wavelength conversion member 13, and the light-emitting element 14. The second covering member 15 is preferably formed of a member having high light reflectivity. Covering the first covering member 11, the light diffusion member 12, the wavelength conversion member 13, and the light-emitting element 14 with the second covering member 15 can reduce light leaking from these members, and light can be efficiently extracted from the light-emitting surface 10. This increases light extraction efficiency of the light-emitting unit 1A. The second covering member 15 can use, for example, a resin material containing a light reflective substance, such as a white pigment. Alternatively, the second covering member 15 may also be a light reflective member formed of an inorganic material containing, for example, boron nitride or alkali metal silicate. In this case, titanium oxide or zirconium oxide can be further contained.

Examples of the light reflective substance included in the second covering member 15 include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide, and preferably, one of these substances is used alone or two or more of these substances are used in combination. For the resin material, a resin material containing a thermosetting resin, such as an epoxy resin, an epoxy modified resin, a silicone resin, a silicone modified resin, or a phenol resin, as a main component is preferably used as a base material. Note that the second covering member 15 may be formed of a member having light transmissivity or light absorbency for visible light as necessary. The member having the light absorbency includes, for example, carbon black.

The first covering member 11 is a member covering at least a part of an upper surface of light diffusion member 12, and is, for example, a member having a substantially rectangular shape in a top view. By disposing the first covering member 11, the upper surface of the light diffusion member 12 can be protected from external force or the like. In the example illustrated in FIG. 5, an upper surface of the first covering member 11 is exposed from the second covering member 15 and serves as the light-emitting surface 10. The first covering member 11 can include a material same as or similar to the material exemplified for the second covering member 15.

The base body 18 is a member formed using ceramic as a main material. Examples of the ceramic include aluminum nitride, silicon nitride, aluminum oxide, and silicon carbide. In the present embodiment, the light source 1 is mounted on the substrate 3 via the base body 18, so that the heat dissipation of the light-emitting module 100 is improved.

In the first example of the light source 1, the first covering member 11 has a thickness in a range of 1 μm to 100 μm, the light diffusion member 12 has a thickness in a range of 10 μm to 200 μm, the wavelength conversion member 13 has a thickness in a range of 20 μm to 200 μm, the light-emitting element 14 has a thickness in a range of 5 μm to 50 μm, and the base body 18 has a thickness in a range of 150 μm to 1000 μm. In addition, a gap Gp between adjacent light-emitting elements 14 is in a range of 5 μm to 100 μm.

In the present embodiment, the light-emitting element 14 is manufactured by a laser lift off (LLO) processing method. The LLO processing method refers to a processing method in which a processing target is irradiated with a high-power laser and a processing surface of the processing target is heated and decomposed, thereby separating one or more members into two or more members with the processing surface as a boundary. For example, the process of manufacturing the light-emitting element 14 includes a process of separating the growth substrate of the light-emitting element from the nitride-based semiconductor by the LLO processing method. By manufacturing the light-emitting element 14 from which the growth substrate such as sapphire is removed by the LLO processing method, the thickness of the light-emitting element 14 is reduced, and light generated in the nitride-based semiconductor of the light-emitting element 14 and absorbed mainly by the growth substrate can be effectively used. That is, light absorbed in the light-emitting element 14 is reduced, and the light extraction efficiency is improved. Thus, the light emission output from the light-emitting element 14 is increased. Note that the light-emitting module 100 may use the light source 1 that does not include the base body 18. In this case, the LLO processing method may be omitted, and the light-emitting element 14 including a growth substrate may be used. In the light source 1 not having the base body 18, the electrode 16 of the light-emitting element 14 and the wiring of the substrate 3 are electrically connected by being connected via a conductive member such as a bump and solder.

The second example of the light source 1 is described below in detail with reference to FIGS. 5 and 6. The same names and reference signs as those in the previously described embodiment indicate the same or similar members or configurations, and detailed descriptions thereof are omitted as appropriate. This applies similarly to modified examples, embodiments, and examples to be described below.

### Second Example of Light Source 1

As illustrated in FIGS. 5 and 6, the light source 1 includes the light-emitting unit 1A including the first light-emitting unit 1A-1 and the second light-emitting unit 1A-2. The light source 1 includes one first light-emitting unit 1A-1, one second light-emitting unit 1A-2, and 8 third light-emitting units 1A-3. The first light-emitting unit 1A-1 and the second light-emitting unit 1A-2 are arranged side by side in the X direction at the central portion 1B of the light source 1, in a top view. For easy understanding, when an area occupied by one first light-emitting unit 1A-1 and one second light-emitting unit 1A-2 is equal to an area occupied by one third light-emitting unit 1A-3 in a top view, the example illustrated in FIG. 5 can be regarded as a 3×3 matrix as a whole. In the following description, the example of the arrangement of the light-emitting units 1A illustrated in FIG. 5 may be regarded as a 3×3 matrix as a whole. The third light-emitting units 1A-3 are disposed vertically or laterally in a top view. In the example illustrated in FIG. 5, in the 3×3 matrix, three third light-emitting units 1A-3 are aligned in each of the first and third rows in the X direction. In addition, three third light-emitting units 1A-3 are aligned in each of the first and third columns in the Y direction. The central portion 1B is located at a position corresponding to the second row and the second column in the 3×3 matrix. Note that in FIG. 5, to avoid complication of the drawing, only the third light-emitting unit 1A-3 disposed in the second row and the first column among the 8 third light-emitting units 1A-3 is denoted by a reference sign.

In the example illustrated in FIG. 6, the third light-emitting unit 1A-3 includes a light-emitting element 14 and a wavelength conversion member 13 disposed above the light-emitting element 14. In addition, the third light-emitting unit 1A-3 includes a light diffusion member 12 disposed above the wavelength conversion member 13, and a second covering member 15 covering the lateral surfaces of the light diffusion member 12, the wavelength conversion member 13, and the light-emitting element 14.

The light-emitting element 14 includes, on a surface opposite to a surface facing the wavelength conversion member 13, that is, on a lower surface thereof, at least a pair of positive and negative electrodes 16. The light-emitting element 14 is disposed on the upper surface 31 of the substrate 3 via the electrodes 16. The lateral surfaces of the electrodes 16 and the lower surface of the light-emitting element 14 are covered with the second covering member 15.

The light source 1 and the substrate 3 are electrically connected by connecting the electrode 16 of the light-emitting element 14 and the wiring of the substrate 3 with a conductive member such as a bump and solder. Note that the configuration, the size, and the like of the wiring of the substrate 3 are set according to the configuration and the size of the electrode 16 of the light-emitting element 14.

The second covering member 15 integrally holds a plurality of light diffusion members 12, a plurality of wavelength conversion members 13, and a plurality of light-emitting elements 14. In the example illustrated in FIG. 6, the second covering member 15 is disposed on the lateral surfaces of the light diffusion member 12, the wavelength conversion member 13, and the light-emitting element 14. The second covering member 15 is disposed between adjacent light diffusion members 12, between adjacent wavelength conversion members 13, and between adjacent light-emitting elements 14, respectively. The second covering member 15 integrally holds the light diffusion member 12, the wavelength conversion member 13, and the light-emitting element 14 included in each of the first light-emitting unit 1A-1, the second light-emitting unit 1A-2, and the 8 third light-emitting units 1A-3. An upper surface of the second covering member 15 constitutes a part of the upper surface of the light source 1. In addition, the second covering member 15 includes two long lateral surfaces and two short lateral surfaces, and the four lateral surfaces constitute a substantially rectangular outer shape of the light source 1 in a top view.

In the second example of the light source 1, the thickness of the light diffusion member 12 is 110 μm, the thickness of the wavelength conversion member 13 is 60 μm, and the thickness of the light-emitting element 14 is 250 μm. In addition, a gap Gp between adjacent light diffusion members 12 is 20 μm.

### Lens 2

The lens 2 includes at least one of a resin material, such as a polycarbonate resin, an acrylic resin, a silicone resin, or an epoxy resin, or a glass material, which is light-transmissive with respect to light emitted from the light source 1. The light-transmissive portion 20 and the first support portion 25 are continuous with each other as a monolithic member. However, the light-transmissive portion 20 and the first support portion 25 may be individual members. In addition, the first support portion 25 may be omitted, and the light-transmissive portion 20 may also function as the first support portion 25. Note that the light transmissivity of the lens 2 refers to a property of allowing 60% or more of light from the light source 1 to be transmitted.

In the example illustrated in FIG. 1, the light-transmissive portion 20 has a substantially circular shape in a top view. However, the light-transmissive portion 20 in a top view is not limited to a substantially circular shape, and may be a substantially rectangular shape, a substantially elliptical shape, a substantially polygonal shape, or the like. In addition, the light-transmissive portion 20 may have a rotationally symmetrical shape in a top view. In consideration that a imaging range of a general imaging device is substantially rectangular, the light-transmissive portion 20 preferably has a four-fold rotationally symmetrical shape or a two-fold rotationally symmetrical shape in a top view.

In the example illustrated in FIG. 2, the light incident surface 21 is a convex surface that is convex toward the location the light source 1. The light exiting surface 22 is a convex surface that is convex toward the location opposite to the light source 1. The light-transmissive portion 20 is a biconvex single lens. The light exiting surface 22 is a spherical surface. However, the light-transmissive portion 20 may be a single meniscus lens. The light exiting surface 22 is not limited to a spherical surface, and may be an aspherical surface.

In the example illustrated in FIG. 1, the first support portion 25 is a cylindrical portion that supports the light-transmissive portion 20 from the outside in a top view. In addition, the first support portion 25 has a continuous circular annular shape in a top view. However, the first support portion 25 in a top view is not limited to a circular annular shape, and may have a rectangular annular shape or a polygonal annular shape. In addition, the first support portion 25 may include a plurality of first support portions 25, and the plurality of first support portions 25 may be annularly disposed in a top view.

### Substrate 3

The substrate 3 is a substrate including wirings on which the light source 1 can be mounted. In the example illustrated in FIGS. 1 and 2, the substrate 3 is a plate-shaped member having a substantially circular shape in a top view. Note that the substrate 3 may have a substantially rectangular shape, a substantially elliptical shape, a substantially polygonal shape, or the like in a top view. In addition, on the substrate 3, an electronic component other than the light source 1 may be further disposed. The electronic component is a Zener diode, a thermistor, a capacitor, a light-receiving sensor, or the like.

Preferably, the substrate 3 uses an insulation material as a base material, and also uses a material that is less likely to transmit light emitted from the light source 1, light incident into the light-emitting module 100 from the outside, or the like. In addition, for the substrate 3, a material having a certain degree of strength is preferably used. Specifically, the substrate 3 can be formed using, as the base material, ceramic such as alumina, aluminum nitride, mullite, or silicon nitride, or a resin such as a phenol resin, an epoxy resin, a polyimide resin, a bismaleimide triazine resin (BT resin), a polyphthalamide, or a polyester resin.

The wirings of the substrate 3 can be formed of at least one type of copper, iron, nickel, tungsten, chromium, aluminum, silver, gold, titanium, palladium, rhodium, an alloy thereof, or the like. In addition, a layer of silver, platinum, aluminum, rhodium, gold, an alloy thereof, or the like may be provided on the surface layer of the wirings of the substrate 3, from the view point of at least one of the wettability of a conductive member and light reflectivity of the wiring.

Behavior of Light Emitted from Light-Emitting Module 100 and Illuminance of Irradiation Light

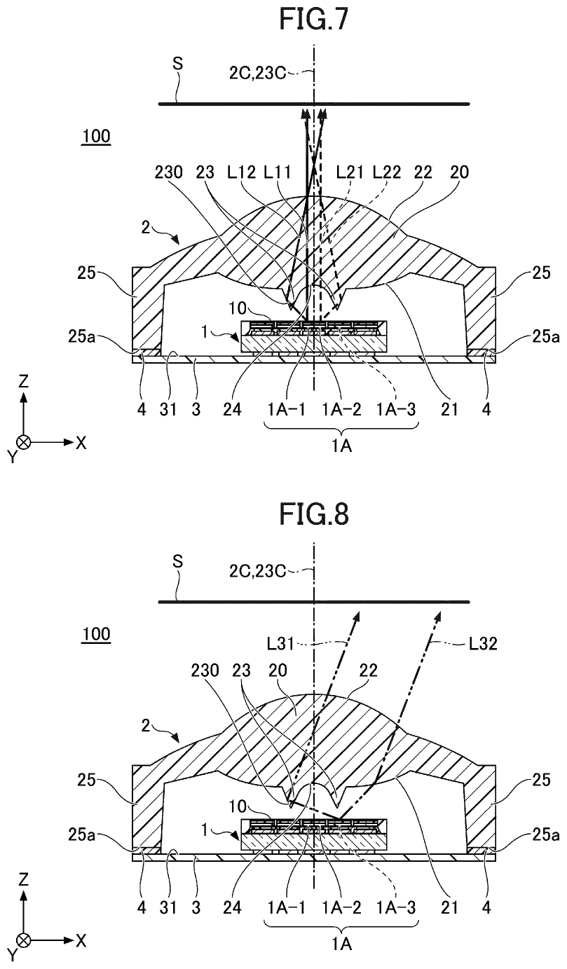

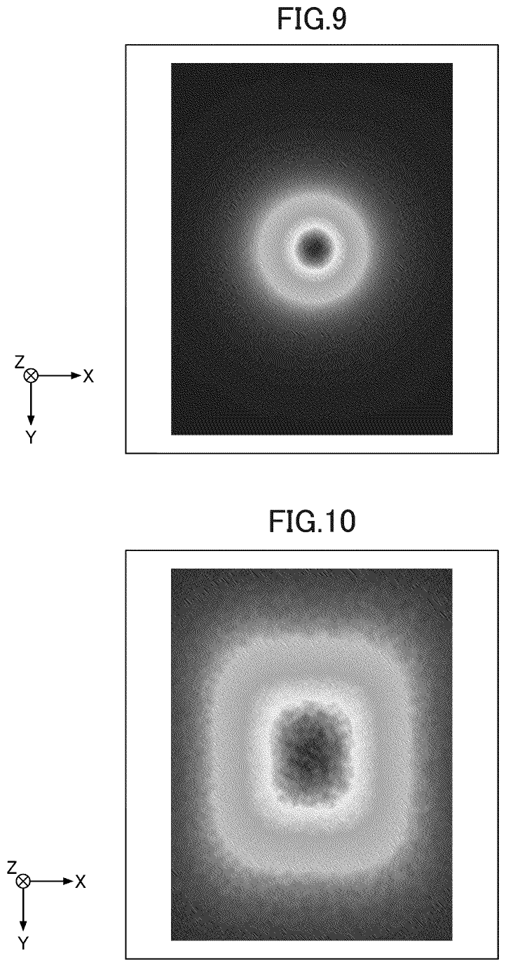

The behavior of light emitted from the light-emitting module 100 and the illuminance of irradiation light are described below with reference to FIGS. 7 to 10. FIG. 7 is a schematic diagram illustrating the behavior of light emitted from each of the first light-emitting unit 1A-1 and the second light-emitting unit 1A-2 of the light source 1 included in the light-emitting module 100. FIG. 8 is a schematic diagram illustrating the behavior of light emitted from the third light-emitting unit 1A-3 of the light source 1. FIG. 9 is a schematic diagram illustrating the illuminance on an irradiation plane when only the first light-emitting unit 1A-1 and the second light-emitting unit 1A-2 are caused to emit light. FIG. 10 is a schematic diagram illustrating the illuminance on the irradiation plane when all the light-emitting units 1A in the light source 1 are caused to emit light.

In FIG. 7, light L11 and light L12 indicated by solid arrows represent a part of light emitted from the first light-emitting unit 1A-1 of the light source 1. The light L11 is emitted from the first light-emitting unit 1A-1, passes through the inner region 24 of the first protrusion 23 in the light incident surface 21, and enters the inside of the lens 2. The light L11 that has entered the inside of the lens 2 exits from the lens 2 through the light exiting surface 22, thereby irradiating an irradiation plane S. In the example illustrated in FIG. 7, the irradiation plane S is a plane orthogonal to the optical axis 2C of the lens 2. The light L12 is emitted from the first light-emitting unit 1A-1, passes through the first protrusion 23 of the light incident surface 21, and enters the inside of the lens 2. The light L12 that has entered the inside of the lens 2 is reflected by the first light reflective surface 230 of the first protrusion 23, and then exits from the lens 2 through the light exiting surface 22, thereby irradiating the irradiation plane S.

Light L21 and light L22 indicated by broken line arrows represent a part of light emitted from the second light-emitting unit 1A-2 of the light source 1. The light L21 is emitted from the second light-emitting unit 1A-2, passes through the inner region 24 of the first protrusion 23 in the light incident surface 21, and enters the inside of the lens 2. The light L21 that has entered the inside of the lens 2 exits from the lens 2 through the light exiting surface 22, thereby irradiating the irradiation plane S. The light L22 is emitted from the second light-emitting unit 1A-2, passes through the first protrusion 23 of the light incident surface 21, and enters the inside of the lens 2. The light L22 that has entered the inside of the lens 2 is reflected by the first light reflective surface 230 of the first protrusion 23, and then exits from the lens 2 through the light exiting surface 22, thereby irradiating the irradiation plane S.

The light L12 with the first chromaticity and the light L22 with the second chromaticity are reflected by the first light reflective surface 230, thereby traveling toward the center of the lens 2 in a top view and exiting from the light exiting surface 22. The light L11 and the light L21 travel substantially straight in the vicinity of the optical axis 2C to be along the optical axis 2C of the lens 2. In a space between the light exiting surface 22 and the irradiation plane S, the light L11 and the light L12 with the first chromaticity and the light L21 and the light L22 with the second chromaticity overlap and are mixed. Thus, color-adjusted light is obtained on the irradiation plane S. The light L11 and the light L21 travel substantially straight, and the light L12 and the light L22 travel toward the center of the lens 2 in a top view. In the case of using only light that travels substantially straight toward the irradiation plane S along the optical axis 2C of the lens 2, such as the light L11 and the light L21, because the amount of light overlapping on the irradiation plane S is small, the degree of color mixing decreases and color unevenness increases. On the other hand, by including light that travels toward the center of the lens 2 in a top view and intersects with each other before reaching the irradiation plane S, such as the light L12 and the light L22, the amount of light overlapping on the irradiation plane S increases, and thus the degree of color mixing increases and the color unevenness decreases. In the light-emitting module 100, when only the first light-emitting unit 1A-1 and the second light-emitting unit 1A-2 among the 26 light-emitting units 1A in the light source 1 are caused to emit light, because the light L11, the light L21, the light L12, and the light L22 travel along the optical axis 2C of the lens 2 (without the light distribution of each light spreading), irradiation light with a narrow-angle light distribution is obtained.

In FIG. 8, light L31 and light L32 indicated by arrows of alternate long and short dash lines represent a part of light emitted from the third light-emitting unit 1A-3 of the light source 1. The light L31 is emitted from the third light-emitting unit 1A-3, passes through the first protrusion 23 of the light incident surface 21, and enters the inside of the lens 2. The light L31 that has entered the inside of the lens 2 is reflected by the first light reflective surface 230 of the first protrusion 23, and then exits from the lens 2 through the light exiting surface 22, thereby irradiating the irradiation plane S. The light L32 is emitted from the third light-emitting unit 1A-3, passes through a region other than the first protrusion 23 and the inner region 24 in the light incident surface 21, and enters the inside of the lens 2. The light L32 that has entered the inside of the lens 2 exits from the lens 2 through the light exiting surface 22, thereby irradiating the irradiation plane S.

The light L31 is reflected by the first light reflective surface 230, thereby traveling toward the center of the lens 2 in a top view and exiting from the light exiting surface 22. On the other hand, the light L32 passes through the region in the light incident surface 21 other than the first protrusion 23 and the inner region 24, and thus exits from the light exiting surface 22 while spreading in a direction away from the optical axis 2C of the lens 2. Because the light L32 spreads, when the light-emitting unit 1A including at least the third light-emitting unit 1A-3 of the light source 1 is caused to emit light, irradiation light of a wide-angle light distribution is obtained.

FIG. 9 illustrates the simulation result of the illuminance on the irradiation plane S of light emitted from the light-emitting module 100 when only the first light-emitting unit 1A-1 and the second light-emitting unit 1A-2 are caused to emit light among the 26 light-emitting units 1A in the light source 1. FIG. 10 illustrates the simulation result of the illuminance on the irradiation plane S of light emitted from the light-emitting module 100 when all of the 26 light-emitting units 1A in the light source 1 are caused to emit light.

As illustrated in FIGS. 9 and 10, when only the first light-emitting unit 1A-1 and the second light-emitting unit 1A-2 are caused to emit light, irradiation light having a narrow-angle light distribution is obtained in comparison with when all of the 26 light-emitting units 1A in the light source 1 are caused to emit light. The irradiation light is color-adjusted light by mixing light beams with the first chromaticity and the light with the second chromaticity.

In the present embodiment, the light distribution angle of light of at least one third light-emitting unit 1A-3 reflected by the first light reflective surface 230 is wider than the light distribution angles of light of the first light-emitting unit 1A-1 and the light of the second light-emitting unit 1A-2 reflected by the first light reflective surface 230. Thus, the light distribution angle of light emitted from the light-emitting module 100 can be controlled by individually controlling the light emission of the plurality of light-emitting units 1A included in the light source 1.

In the present embodiment, light with the first chromaticity and light with the second chromaticity reflected by the first light reflective surface 230 travel toward the center of the lens 2 in a top view. This can make it easier for the light with the first chromaticity and the light with the second chromaticity to be mixed on the irradiation plane. As a result, light with reduced color unevenness is obtained.

Relationship Between Distance from Optical Axis 2C to Annular First Protrusion 23 and Irradiation Light Characteristics

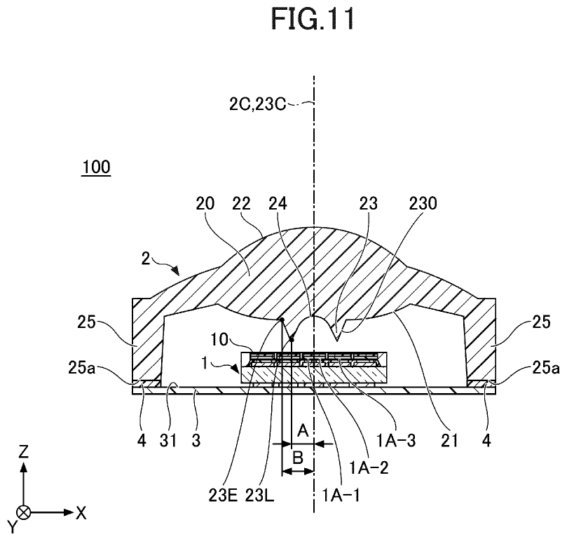

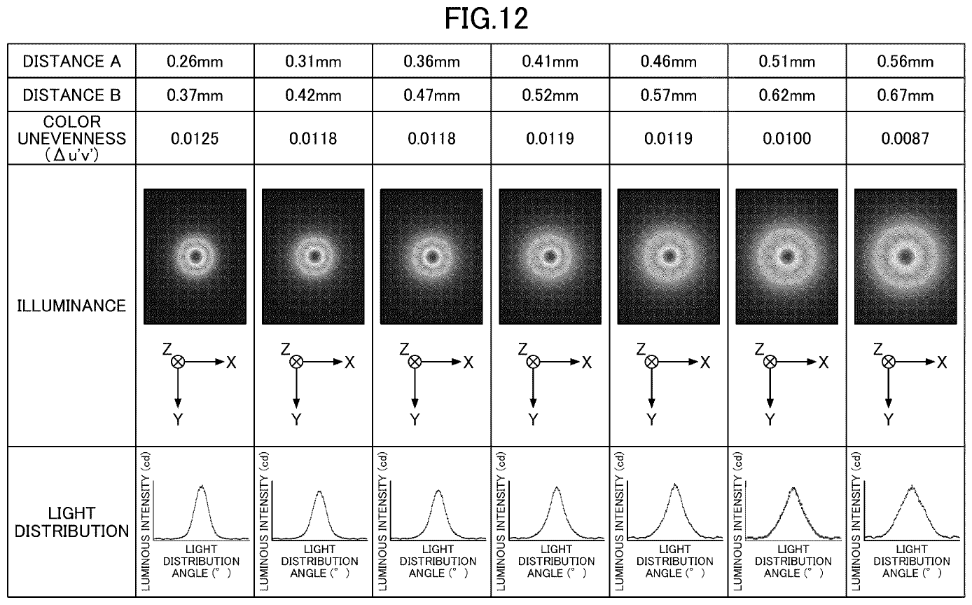

The relationship between the distance from the optical axis 2C of the lens 2 included in the light-emitting module 100 to the annular first protrusion 23 and the irradiation light characteristics is described below with reference to FIGS. 11 and 12. FIG. 11 is a schematic diagram for illustrating the distance from the optical axis 2C of the lens 2 to the annular first protrusion 23. FIG. 12 is a diagram illustrating an example of the relationship between the distance from the optical axis 2C to the annular first protrusion 23 in the lens 2 and optical characteristics.

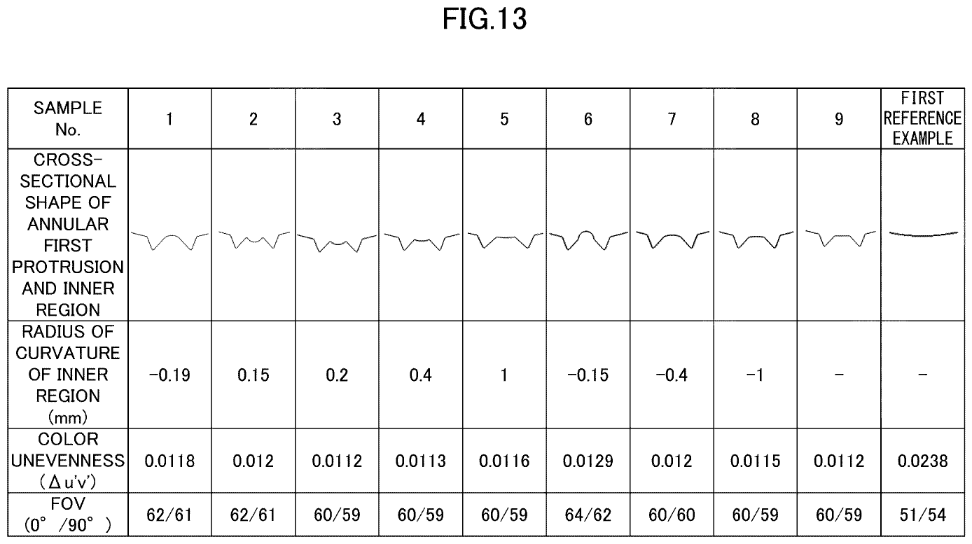

As illustrated in FIG. 11, a distance A is the shortest length between the optical axis 2C and a portion 23L of the annular first protrusion 23 located at the lowest position in a cross section including the optical axis 2C. On the other hand, a distance B is the shortest length between the optical axis 2C and the outer edge 23E of the annular first protrusion 23 in the cross section including the optical axis 2C. FIG. 12 illustrates the simulation results of the color unevenness Δu′v′ of light emitted from the light-emitting module 100, the illuminance obtained on the irradiation plane, and light distribution, when only the first light-emitting unit 1A-1 and the second light-emitting unit 1A-2 of the light-emitting module 100 are caused to emit light and the distances A and B are changed. In the example illustrated in FIG. 12, 0.36 mm was used as a reference of the distance A, and 0.47 mm was used as a reference of the distance B. In each of the examples illustrated in FIGS. 12 and 13, a distance from the light-emitting surface 10 of the light source 1 to the irradiation plane was 150 mm.

Au′v′ is a value calculated to evaluate the color unevenness of light emitted from the light-emitting module 100, and the smaller the value of Au′v′ is, the smaller the color unevenness is. As a method for calculating Au′v′, the following (1) to (5) were performed in order. (1) The u′ and the v′ were calculated at 21209 measurement points in a rectangular irradiation region on the irradiation plane. The 21209 measurement points were located at the centers of a total of 21209 cells obtained by dividing the irradiation region into 167 cells in the vertical direction and 127 cells in the lateral direction, each cell being a square of 2.5 mm×2.5 mm. (2) The mean values <u′> and <v′> of all the measurement points were calculated. (3) For each measurement point, Δuₙ=|u′ₙ−<u′>| and Δvₙ=|v′ₙ−<v′>| were calculated to obtain (Δu′ₙ, Δv′ₙ). (4) Based on the following Equation I, a distance (Δu′v′)ₙ between Δu′ and Δv′ was calculated. (5) The maximum value among the values of (Δu′v′)ₙ was defined as Δu′v′.

$$\begin{matrix}Math 1 & \\ {( Δ {u}^{′} {v}^{′} )}_{n} = \sqrt{{( Δ {u}_{n}^{′} )}^{2} + {( Δ {v}_{n}^{′} )}^{2}} & ( I )\end{matrix}$$

The light distribution illustrated in FIG. 12 is a graph showing the peak of a luminous intensity value in the 0° direction when the direction passing through the central position of the irradiation region and parallel to the X axis is defined as the 0° direction on the irradiation plane irradiated by the light-emitting module 100. The narrower the peak width of the luminous intensity value is, the narrower the angle of light distribution is, and the wider the peak value of the luminous intensity value is, the wider the angle of light distribution is.

As illustrated in FIG. 12, the color unevenness Δu′v′ hardly changed or decreased even when the distances A and B were longer than the reference. The color unevenness Δu′v′ increased as the distances A and B became shorter than the reference. In addition, as the distances A and B became larger than the reference, the light distribution became wider and the illuminance became lower. From the above, it was found that the condition that the distances A and B are 0.36 mm and 0.47 mm, respectively, is most preferable to adjust the color of the irradiation light and to achieve a narrow-angle light distribution when only the first light-emitting unit 1A-1 and the second light-emitting unit 1A-2 are caused to emit light. It was found that, when only the suitable adjustment of the color of the irradiation light is taken into consideration without considering the light distribution to be a wide angle, it is preferable that the distance A is longer than 0.36 mm and the distance B is longer than 0.47 mm, and it is more preferable that the distance A is equal to or longer than 0.51 mm and the distance B is equal to or longer than 0.62 mm.

### Relationship Between Shapes of Annular First Protrusion 23 and Inner Region 24 and Irradiation Light Characteristics

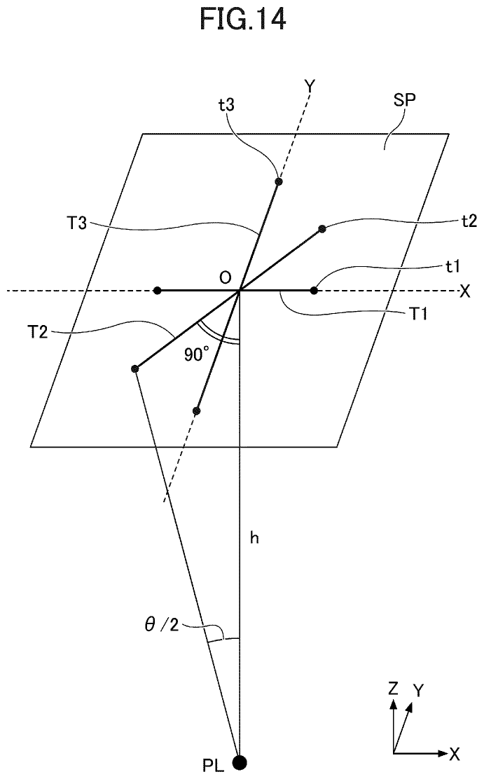

The relationship between the shapes of the annular first protrusion 23 and the inner region 24 of the lens 2 included in the light-emitting module 100 and the irradiation light characteristics is described below with reference to FIGS. 13 and 14. FIG. 13 is a diagram illustrating an example of the relationship between the shapes of the annular first protrusion 23 and the inner region 24 of the lens 2 included in the light-emitting module 100 and the optical characteristics in samples No. 1 to 9. FIG. 14 is a schematic diagram illustrating the illuminance on an irradiation plane of light emitted from the light source. In the samples No. 1 to 9, only the first light-emitting unit 1A-1 and the second light-emitting unit 1A-2 of the light-emitting module 100 were caused to emit light.

In FIG. 13, the “cross-sectional shape of annular first protrusion and inner region” schematically illustrates the cross-sectional shape of the annular first protrusion 23 and the inner region 24 in one cross section including the optical axis 2C of the lens 2. The “radius of curvature of the inner region” represents the radius of curvature of the inner region 24, and the radius of curvature when the inner region 24 is a concave surface that is recessed toward the location opposite to the light source is a negative value, and the radius of curvature when the inner region 24 is a convex surface that is convex toward the light source 1 is a positive value. “Color unevenness (Δu′v′)” is a simulation result of the color unevenness Δu′v′. “FOV” is a field of view. A first reference example shows the relationship between the shape of a lens of a light-emitting module and irradiation light characteristics in the case of using the light-emitting module having the same configuration as the light-emitting module 100 except that the lens has no annular first protrusion and inner region. Also in the first reference example, as in the samples No. 1 to 9, only the first light-emitting unit and the second light-emitting unit of the light-emitting module were caused to emit light.

The FOV that is the evaluation item is described below with reference to FIG. 14. An irradiation angle refers to an angle at which illuminance on an irradiation region SP (in other words, on the XY plane of the irradiation region SP) is 10% with respect to the maximum illuminance of 100%. For example, as illustrated in FIG. 14, when the irradiation region SP, which is an irradiation range, is irradiated with light from a light source PL located at a distance h in the vertical direction (Z-axis direction) from a central position O of the irradiation region SP, the maximum illuminance is obtained at the central position O of the irradiation range. When the illuminance at the central position O is 100%, a position at which the illuminance is 10% in the irradiation region SP is defined as an outer edge position t. In the present example, the items (2) to (4) were evaluated by calculating an irradiation angle θ that was determined based on the positional relationship between two outer edge positions t and the light source PL, and the smaller irradiation angle θ was regarded to be more preferable.

FOV (0°) was defined such that, in the irradiation region SP, positions at which illuminance are 10% in a direction (0° direction) passing through the central position O and parallel to the X-axis were defined as outer edge positions t1 and a distance T between two outer edge positions t1 was defined as T1. FOV (45°) was defined such that, in the irradiation region SP, positions at which illuminance are 10% in a direction (45° direction) passing through the central position O and inclined at 45° with respect to the X-axis were defined as outer edge positions t2 and a distance T between two outer edge positions t2 was defined as T2. FOV (90°) was defined such that, in the irradiation region SP, positions at which illuminance are 10% in a direction (90° direction or a direction parallel to the Y-axis) passing through the central position O and perpendicular to the X-axis were defined as outer edge positions t3 and a distance T between two outer edge positions t3 was defined as T3. In the present example, for FOV (0°) and FOV (90°), as an example, a distance h was set to 150 mm, and the distances T (T1 and T3) were substituted into the following Equation II to calculate the irradiation angle θ of irradiation light having the narrow-angle light distribution.

$$\begin{matrix}Math 2 & \\ θ = 2 \times Arc tan \frac{T / 2}{h} \times 180 / π & ( II )\end{matrix}$$

As illustrated in FIG. 13, in all of the samples No. 1 to 9, the effect of reducing color unevenness was obtained in comparison with the first reference example. This is because, in the samples No. 1 to 9, light with the first chromaticity emitted by the first light-emitting unit 1A-1 and light with the second chromaticity emitted by the second light-emitting unit 1A-2 were reflected and converged by the first light reflective surface 230 of the annular first protrusion 23, and traveled toward the optical axis 2C of the lens 2 in a top view, so that the absolute amount of light overlapping each other on the irradiation plane was larger than that in the first reference example. In addition, in the samples No. 1 to 9, the cross-sectional shape and the magnitude of the radius of curvature of the inner region 24 did not significantly affect the color unevenness. That is, it was found that the effect of reducing the color unevenness is more affected by the annular first protrusion 23 than by the radius of curvature of the inner region 24 and whether the inner region 24 is a concave surface or a convex surface. Accordingly, as long as the lens 2 includes at least the annular first protrusion 23, the cross-sectional shape and the magnitude of the radius of curvature of the inner region 24 are not particularly limited. Moreover, in all of the samples No. 1 to 9, the irradiation angle of the irradiation light having the narrow-angle light distribution could be maintained to be substantially equal to that of the first reference example.

### Modified Examples

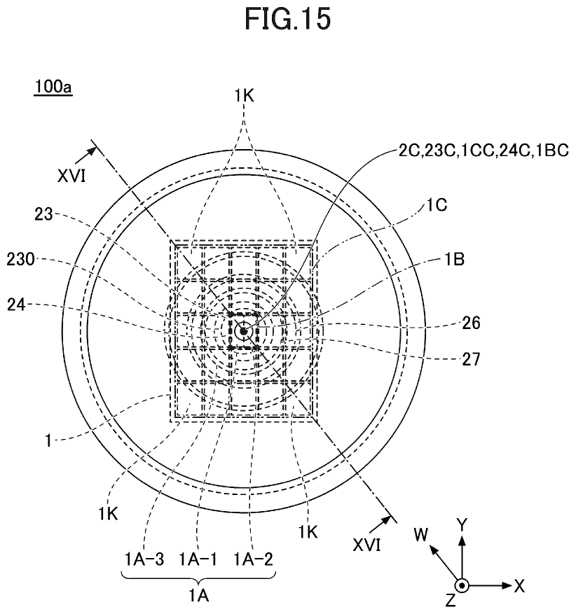

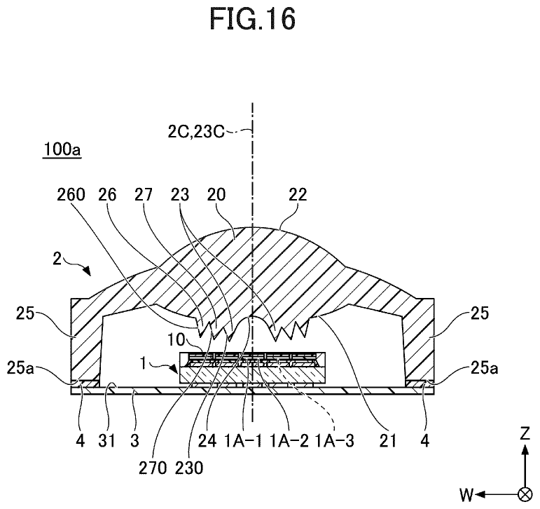

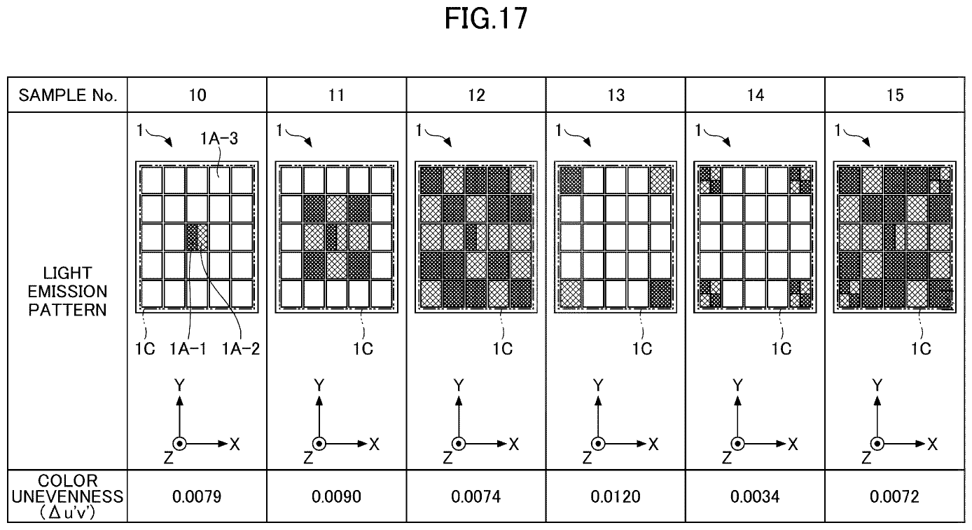

A light-emitting module according to a modified example of the first embodiment is described below with reference to FIGS. 15 to 17. FIG. 15 is a schematic top view of a light-emitting module 100a according to the modified example of the first embodiment. FIG. 16 is a schematic cross-sectional view taken along line XVI-XVI in FIG. 15. FIG. 17 is a schematic diagram illustrating an example of color unevenness Δu′v′ when the light emission pattern of the light source 1 included in the light-emitting module 100a is changed.

In the light-emitting module 100a according to the present modified example, the light-emitting region 1C of the light source 1 has a rectangular shape in a top view. The lens 2 further includes an annular second protrusion 26 outward of the annular first protrusion 23. The annular second protrusion 26 overlaps at least one of the four corner portions 1K of the light-emitting region 1C in a top view. In these respects, the light-emitting module 100a is different from the light-emitting module 100 according to the first embodiment.

In the example illustrated in FIGS. 15 and 16, the lens 2 further includes an annular third protrusion 27 between the annular first protrusion 23 and the annular second protrusion 26 in a top view. The annular second protrusion 26 includes a second light reflective surface 260. The annular third protrusion 27 includes a third light reflective surface 270. The annular second protrusion 26 overlaps each of the four corner portions 1K of the light-emitting region 1C in a top view. In a top view, the annular third protrusion 27 overlaps four light-emitting units 1A disposed between the central portion 1B of the light source 1 and the four corner portions 1K, among eight light-emitting units 1A located around the central portion 1B of the light source 1.

Light emitted from the light-emitting unit 1A becomes more difficult to control as the light-emitting unit 1A is farther away from the optical axis 2C of the lens 2. The four corner portions 1K of the light-emitting region 1C are farther from the optical axis 2C of the lens 2 than the center 1CC of the light-emitting region 1C. Therefore, most of light emitted from the four corner portions 1K of the light-emitting region 1C is difficult to control with the lens 2, and the light is likely to become stray light. In the present modified example, in a top view, the annular second protrusion 26 is disposed outside the annular first protrusion 23, and light beams emitted from the four corner portions 1K of the light-emitting region 1C are controlled by the annular second protrusion 26. Thus, the stray light can be reduced. The annular third protrusion 27 converges light beams emitted from the eight light-emitting units 1A located around the central portion 1B of the light source 1 (in other words, the light-emitting units 1A adjacent to at least one of the first light-emitting unit 1A-1 and the second light-emitting unit 1A-2 disposed at the central portion 1B) toward the optical axis 2C of the lens 2.

The color unevenness Δu′v′ was evaluated for each of the samples No. 10 to 15 in which the light emission patterns of the light source 1 of the light-emitting module 100a were changed. FIG. 17 illustrates the color unevenness Δu′v′ for each of the various light emission patterns of the light source 1. In the light emission patterns of the samples No. 10 to 15 of the example illustrated in FIG. 17, the first light-emitting unit 1A-1 is indicated by a dark dot pattern, the second light-emitting unit 1A-2 is indicated by a cross-hatching, and the third light-emitting unit 1A-3 is indicated by white. In FIG. 17, the first light-emitting unit 1A-1 and the second light-emitting unit 1A-2 are caused to emit light, and the third light-emitting unit 1A-3 is not caused to emit light. In FIG. 17, to avoid complication of the drawing, only the light source 1 according to the sample No. 10 is denoted by the reference signs of the first light-emitting unit 1A-1, the second light-emitting unit 1A-2, and the third light-emitting unit 1A-3.

The light source 1 according to the sample No. 10 includes one first light-emitting unit 1A-1 and one second light-emitting unit 1A-2, and the one first light-emitting unit 1A-1 and the one second light-emitting unit 1A-2 are caused to emit light. The light source 1 according to the sample No. 11 includes five first light-emitting units 1A-1 and five second light-emitting units 1A-2, and the five first light-emitting units 1A-1 and the five second light-emitting units 1A-2 are caused to emit light. The light source 1 according to the sample No. 12 includes thirteen first light-emitting units 1A-1 and thirteen second light-emitting units 1A-2, and the thirteen first light-emitting units 1A-1 and the thirteen second light-emitting units 1A-2 are caused to emit light. The light source 1 according to the sample No. 13 includes two first light-emitting units 1A-1 diagonally disposed at two of the four corner portions in a top view and two second light-emitting units 1A-2 diagonally disposed at the other two thereof, and the two first light-emitting units 1A-1 and the two second light-emitting units 1A-2 are caused to emit light.

In the light source 1 according to the sample No. 14, the first light-emitting unit 1A-1 and the second light-emitting unit 1A-2 are disposed at each of the four corner portions of the light-emitting region 1C. In the example illustrated in FIG. 17, two first light-emitting units 1A-1 are diagonally disposed at each of the four corner portions of the light-emitting region 1C. In addition, two second light-emitting units 1A-2 are diagonally disposed at each of the four corner portions of the light-emitting region 1C. Accordingly, the light source 1 according to the sample No. 14 includes eight first light-emitting units 1A-1 and eight second light-emitting units 1A-2, and the eight first light-emitting units 1A-1 and the eight second light-emitting units 1A-2 are caused to emit light.

The light source 1 according to the sample No. 15 includes 17 first light-emitting units 1A-1 and 15 second light-emitting units 1A-2, and the 17 first light-emitting units 1A-1 and the 15 second light-emitting units 1A-2 are caused to emit light.

As illustrated in FIG. 17, it was found that the color unevenness Δu′v′ was reduced and adjustment was possible in each of the samples No. 10 to 15. In the sample No. 11, the annular third protrusion 27 was able to adjust the colors of light beams with different chromaticities emitted from the five first light-emitting units 1A-1 and the five second light-emitting units 1A-2 while reducing the color unevenness Δu′v′. In particular, in the sample No. 14, the color unevenness Δu′v′ was able to be reduced most. From the above, it was found that the color unevenness Δu′v′ can be further reduced and the color can be adjusted by including the first light-emitting unit 1A-1 and the second light-emitting unit 1A-2 having chromaticities different from each other at each of the four corner portions of the light-emitting region 1C and the annular second protrusion 26 overlapping the four corner portions 1K of the light-emitting region 1C (in other words, the first light-emitting unit 1A-1 and the second light-emitting unit 1A-2 are disposed at each of the four corner portions of the light-emitting region 1C). Although the first light-emitting unit 1A-1 and the second light-emitting unit 1A-2 are disposed at each of the four corner portions of the light-emitting region 1C in the sample No. 14, the first light-emitting unit 1A-1 and the second light-emitting unit 1A-2 may be disposed in at least one of the four corner portions of the light-emitting region 1C.

### Second Embodiment

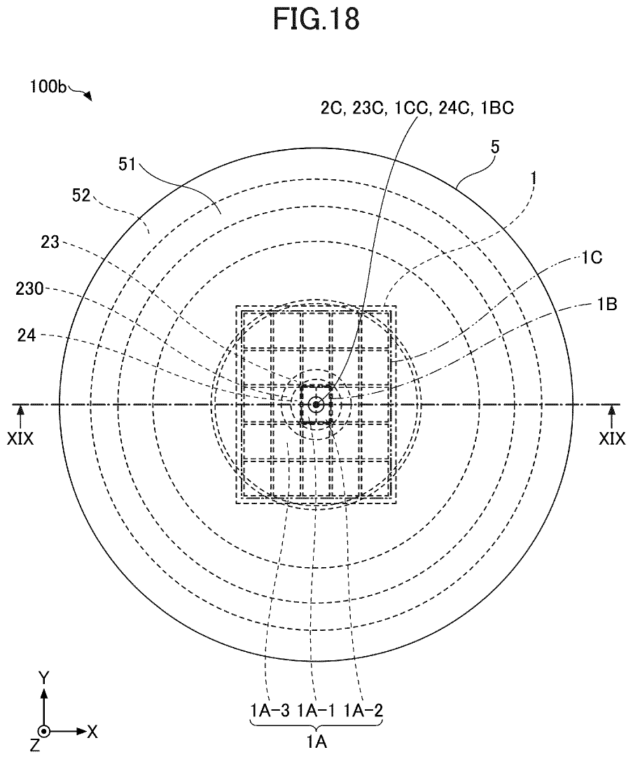

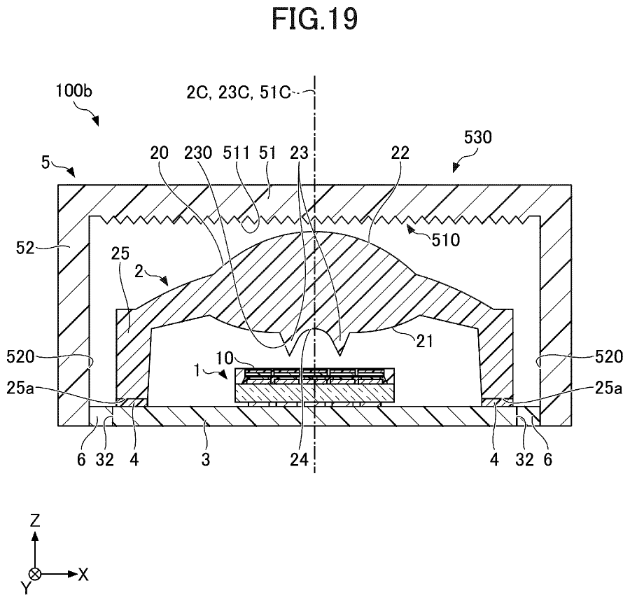

A light-emitting module according to a second embodiment is described below with reference to FIGS. 18 and 19. FIG. 18 is a schematic top view of a light-emitting module 100b according to the second embodiment. FIG. 19 is a schematic cross-sectional view taken along line XIX-XIX in FIG. 18.

As illustrated in FIGS. 18 and 19, the light-emitting module 100b according to the present embodiment is different from the light-emitting module 100 according to the first embodiment in that the light-emitting module 100b further includes a light-transmissive member 5 including a cover portion 51 including a light diffusion portion 511 and the light diffusion portion 511 covers the light exiting surface 22 of the lens 2.

In the example illustrated in FIG. 18, an outer shape of the light-emitting module 100b is substantially circular in a top view. In a top view, the outer shape of the light-transmissive member 5 is the outer shape of the light-emitting module 100b. However, the outer shapes of the light-emitting module 100b and the light-transmissive member 5 are not limited to substantially circular shapes in a top view and may have other shapes such as substantially elliptical shapes, substantially rectangular shapes, or substantially polygonal shapes.

In the example illustrated in FIG. 19, the light-transmissive member 5 further includes a second support portion 52 supporting the cover portion 51. The light-emitting module 100b further includes a second adhesive member 6 disposed between an outer lateral surface 32 of the substrate 3 and an inner lateral surface 520 of the second support portion 52 of the light-transmissive member 5. The cover portion 51 faces the light exiting surface 22 of the lens 2.

By including the light-transmissive member 5, the light-emitting module 100b can perform light distribution control by using the light-transmissive portion 20 of the lens 2 and the cover portion 51 of the light-transmissive member 5, so that a degree of freedom in light distribution control increases.

### Light-Transmissive Member 5

The light-transmissive member 5 covers the lens 2. The cover portion 51 transmits light that is emitted from the light source 1 and has passed through the lens 2. The light-transmissive member 5 includes at least one of a resin material, such as a polycarbonate resin, an acrylic resin, a silicone resin, or an epoxy resin, or a glass material, which is light-transmissive with respect to the light emitted from the light source 1. The light transmissivity of the cover portion 51 preferably has a property of allowing 60% or more of light emitted from the light source 1 to be transmitted.

In the example illustrated in FIG. 19, the cover portion 51 and the second support portion 52 are monolithic without using an adhesive member. From another viewpoint, the cover portion 51 is continuous with the second support portion 52. However, the cover portion 51 and the second support portion 52 may be individual members bonded with an adhesive member.

In the example illustrated in FIGS. 18 and 19, the lens 2 has a light incident surface 21 (hereinafter, may be referred to as a first light incident surface 21 in the present embodiment) and a light exiting surface 22 (hereinafter, may be referred to as a first light exiting surface 22 in the present embodiment), and the cover portion 51 of the light-transmissive member 5 has a second light incident surface 510 facing the first light exiting surface 22 of the lens 2, and a second light exiting surface 530 located opposite to the light source 1 with respect to the second light incident surface 510. The light diffusion portion 511 is provided on the second light incident surface 510. The light diffusion portion 511 includes a plurality of concentric protrusions centered on a central axis 51C of the cover portion 51. The central axis 51C of the cover portion 51 overlaps the optical axis 2C of the lens 2, the central axis 23C of the annular first protrusion 23, the center 1CC of the light-emitting region 1C of the light source 1, the center 24C of the inner region, and the center 1BC of the central portion 1B of the light source 1 in a top view. The light diffusion portion 511 may be a Fresnel lens having a Fresnel shape.

The second support portion 52 supports the cover portion 51 such that the cover portion 51 is disposed above the light-transmissive portion 20. The second support portion 52 is a circular annular portion of the light-transmissive member 5 in a top view. The second support portion 52 is a cylindrical portion extending downward while being outward of the substrate 3 and the lens 2. The second support portion 52 is disposed with a part of the inner lateral surface 520 facing the outer lateral surface 32 of the substrate 3. The second adhesive member 6 is disposed between the outer lateral surface 32 of the substrate 3 and the inner lateral surface 520 of the second support portion 52 of the light-transmissive member 5, so that the light-transmissive member 5 is fixed to the substrate 3.

### EXAMPLES AND REFERENCE EXAMPLES

Examples and Reference Examples are described below. However, the present invention is not limited to these examples.

In the examples and the reference examples, items (1) and (2) below were evaluated in the light-emitting module according to each of a first example, a second example, and a second reference example.
(1) Center illuminance (lux) on a diffusion plate 1 m away from the second light exiting surface of the light-emitting module
(2) Color unevenness Δu′v′

With respect to the above item (1), center illuminance (lux) in each of the narrow-angle light distribution, the wide-angle light distribution, and the super-wide-angle light distribution was evaluated. In the light-emitting module according to each of the first example, the second example, and the second reference example, a narrow-angle mode for emitting narrow-angle light distribution was specified to either a mode (A) in which some of the 24 third light-emitting units 1A-3, the first light-emitting unit 1A-1, and the second light-emitting unit 1A-2 were caused to emit light, or a mode (B) in which the 24 third light-emitting units 1A-3 were not caused to emit light and the first light-emitting unit 1A-1 and the second light-emitting unit 1A-2 were caused to emit light. In the light-emitting module according to each of the first example, the second example, and the second reference example, a wide-angle mode for emitting wide-angle light distribution or super-wide-angle light distribution was specified to any one of a mode (a) in which only some of the 24 third light-emitting units 1A-3 were caused to emit light, a mode (b) in which all of the 24 third light-emitting units 1A-3 were caused to emit light and the first light-emitting unit 1A-1 and the second light-emitting unit 1A-2 were not caused to emit light, or a mode (c) in which all of the 24 third light-emitting units 1A-3, the first light-emitting unit 1A-1, and the second light-emitting unit 1A-2 were caused to emit light. Table 1 shows the specifications of the light-emitting modules according to the first example, the second example, and the second reference example. Note that, in the second example, current values applied to the 24 third light-emitting units 1A-3 were made different between the wide-angle light distribution and the super-wide-angle light distribution.

With respect to the above item (2), the color unevenness of light with the narrow-angle light distribution emitted from the light-emitting module was evaluated by Δu′v′ when the light-emitting module according to each of the first example, the second example, and the second reference example was used as a light source device for a flashlight/torch. In the light-emitting module according to each of the first example, the second example, and the second reference example, the narrow-angle mode for emitting narrow-angle light distribution was specified to the mode (B) in which 24 third light-emitting units 1A-3 were not caused to emit light and the first light-emitting unit 1A-1 and the second light-emitting unit 1A-2 were caused to emit light.

TABLE 1

| | Specification | | |
|---|---|---|---|
| | Narrow-angle | Wide-angle | Super-wide-angle |
| | light | light | light |
| | distribution | distribution | distribution |
| First example | A | c | b |
| Second example | A | c | c |
| Second reference | A | a | b |
| example | | | |

### Evaluation Results

Table 2 shows the evaluation results of the light-emitting modules according to the first example, the second example, and the second reference example. Note that meanings of “⊚,” “◯,” and “Δ” in Table 2 are as follows. In addition, the target value of the item (1) refers to an illuminance at which a sufficient amount of light can be provided to the irradiation region in the wide-angle mode or the narrow-angle mode. The target value of the item (2) refers to that the color unevenness of the irradiation light is a small value when the light-emitting module is used as a light source device for a flashlight/torch.
“⊚”: sufficiently satisfies the target value.
“◯”: satisfies the target value.
“Δ”: does not satisfy the target value.

TABLE 2

| | | | | Second |
|---|---|---|---|---|
| | | First | Second | reference |
| Item | | example | example | example |
| Center | Narrow-angle | ◯ | ⊚ | ⊚ |
| illuminance | light distribution | | | |
| @ 1 m | Wide-angle | ◯ | ⊚ | ◯ |
| | light distribution | | | |
| | Super-wide-angle | ◯ | ⊚ | Δ |
| | light distribution | | | |
| Color unevenness | Δu‘v’ | ⊚ | ◯ | Δ |

### First Example

In the first example, optical characteristics of the light-emitting module 100b according to the second embodiment were evaluated. The materials of the lens 2 and the light-transmissive member 5 of the light-emitting module 100b were a polycarbonate resin. In the first example, the illuminance in the narrow-angle light distribution, the illuminance in the wide-angle light distribution, and the illuminance in the super-wide-angle light distribution were all rated as “◯.” The color unevenness Δu′v′ was rated as “⊚.” Accordingly, in the first example, all of the items satisfied the target values.

### Second Example

In the second example, the optical characteristics of the light-emitting module having different light distribution characteristics were evaluated by changing the radius of curvature of the inner region 24 of the lens 2 (in other words, changing the shapes of the annular first protrusion 23 and the inner region 24 of the lens 2) from those in the first example. In the second example, the illuminance in the narrow-angle light distribution, the illuminance in the wide-angle light distribution, and the illuminance in the super-wide-angle light distribution were all rated as “⊚.” The color unevenness Δu′v′ was rated as “◯.” Accordingly, in the second example, all of the items satisfied the target values.

### Second Reference Example

In the second reference example, the optical characteristics of the light-emitting module were evaluated, which was different from the light-emitting module 100b according to the second embodiment only in that the lens 2 does not include the annular first protrusion 23 and the inner region 24. In the second reference example, the illuminance in the narrow-angle light distribution was rated as “⊚”, the illuminance in the wide-angle light distribution was rated as “◯”, and the illuminance in the super-wide-angle light distribution was rated as “Δ”. The color unevenness Δu′v′ was rated as “A”. Accordingly, in the second reference example, the illuminance in the super-wide-angle light distribution and the color unevenness Δu′v′ did not satisfy the target values.

From the results shown in Table 2 above, it was found that the first example and the second example were superior to the second reference example. It was also found that the first example was slightly superior to the second example in the color unevenness Δu′v′ and the second example was slightly superior to the first example in the illuminance in each of the narrow-angle light distribution, the wide-angle light distribution, and the super-wide-angle light distribution.

While preferred embodiments have been described in detail above, the present invention is not limited to the above-described embodiments. Various modifications and substitutions can be made to the above-described embodiments without departing from the scope of the claims.

The ordinal numbers, quantity, and other numbers used in the description of the embodiments are all exemplified to specifically describe the technique of the present disclosure, and the present disclosure is not limited to the numbers exemplified. In addition, the connection relationship between the components is exemplified to specifically describe the technique of the present disclosure, and the connection relationship for implementing the function of the present invention is not limited thereto.

The lens and the light-emitting module of the present disclosure can control light distribution, and thus are suitable for use in applications such as lighting, camera flashes, and in-vehicle headlights. However, the lens and the light-emitting module of the present disclosure are not limited to these applications.

### REFERENCE SIGNS LIST

1, 1D Light source
1A Light-emitting unit
1A-1 First light-emitting unit
1A-2 Second light-emitting unit
1A-3 Third light-emitting unit
1B Central portion
1BC Center
1C Light-emitting region
1CC Center
1K Corner portion
2 Lens
2C Optical axis
3 Substrate
4 First adhesive member
5 Light-transmissive member
6 Second adhesive member
10 Light-emitting surface
11 First covering member
12 Light diffusion member
13 Wavelength conversion member
14 Light-emitting element
15 Second covering member
16 Electrode
17 First wiring member
18 Base body
19 Second wiring member
20 Light-transmissive portion
21 Light incident surface
22 Light exiting surface
23 First protrusion
23C Central axis
24 Inner region
24C Center
25 First support portion
25a Lower surface
26 Second protrusion
27 Third protrusion
31 Upper surface
32 Outer lateral surface
51 Cover portion
51C Central axis
52 Second support portion
100, 100a, 100b Light-emitting module
150 Resin member
230 First light reflective surface
260 Second light reflective surface
270 Third light reflective surface
510 Second light incident surface
511 Light diffusion portion
520 Inner lateral surface
530 Second light exiting surface
A, B Distance
d Distance
G Outer edge position
Gp Gap
h Distance
L11, L12, L21, L22, L31, L32 Light
m Distance
O Central position
P Point
PL Light source
S Irradiation plane
Wx1, Wx2, Wx3, Wy1, Wy2, Wy3 Width
θ Irradiation angle

What is claimed is:

1. A light-emitting module comprising:
a light source comprising a first light-emitting unit configured to emit light with a first chromaticity and a second light-emitting unit configured to emit light with a second chromaticity different from the first chromaticity; and
a lens having a light incident surface and a light exiting surface and comprising, at the light incident surface, a first protrusion having an annular shape, the first protrusion having a first light reflective surface, wherein:
the light incident surface of the lens faces the light source, and
the first light-emitting unit and the second light-emitting unit are located inward of the first light reflective surface of the first protrusion in a top view.

2. The light-emitting module according to claim 1, wherein:
the light source further comprises a plurality of third light-emitting units that are each configured to emit light with a third chromaticity different from the first chromaticity and the second chromaticity, and
in the top view:
the first light-emitting unit and the second light-emitting unit are located at a central portion of the light source,
the plurality of third light-emitting units are located around the central portion of the light source, and
the first light-emitting unit, the second light-emitting unit,
and the plurality of third light-emitting units are integrally formed.

3. The light-emitting module according to claim 1, wherein:
the light source further comprises a plurality of third light-emitting units that are each configure to emit light with a third chromaticity different from the first chromaticity and the second chromaticity,
a color temperature of light with the third chromaticity is in a range between a color temperature of light with the first chromaticity and a color temperature of light with the second chromaticity, and
in the top view:
the first light-emitting unit and the second light-emitting unit are located at a central portion of the light source, and
the plurality of third light-emitting units are located around the central portion of the light source.

4. The light-emitting module according to claim 2, wherein a light distribution angle of light of at least one of the plurality of third light-emitting units reflected by the first light reflective surface is wider than a light distribution angle of light of the first light-emitting unit and a light distribution angle of light of the second light-emitting unit each reflected by the first light reflective surface.

5. The light-emitting module according to claim 1, wherein light with the first chromaticity and light with the second chromaticity each reflected by the first light reflective surface travel toward a center of the lens in the top view.

6. The light-emitting module according to claim 1, wherein the lens is a biconvex lens.

7. The light-emitting module according to claim 1, wherein an inner region of the light incident surface surrounded by the first protrusion is a concave surface that is recessed in a direction opposite to a direction in which the light source is located.

8. The light-emitting module according to claim 1, wherein an optical axis of the lens overlaps a center of an inner region surrounded by the first protrusion in the top view.

9. The light-emitting module according to claim 8, wherein the inner region surrounded by the first protrusion overlaps a center of a central portion of the light source in the top view.

10. The light-emitting module according to claim 1, wherein light emission output of each of the first light-emitting unit and the second light-emitting unit is changeable based on an output of an outside air temperature sensor.

11. The light-emitting module according to claim 1, wherein:
where m and n are positive integers different from each other, the light source comprises a plurality of light-emitting units of m rows×m columns as a whole or m rows×n columns as a whole,
in the top view, the first light-emitting unit and the second light-emitting unit are located at a central portion of the light source.

12. The light-emitting module according to claim 1, wherein:
in the top view:
a light-emitting region of the light source is rectangular, and
the first light-emitting unit and the second light-emitting unit are disposed at at least one of four corner portions of the light-emitting region.

13. The light-emitting module according to claim 12, wherein:
the lens further comprises a second protrusion having an annular shape and located outward of the first protrusion, and
the second protrusion overlaps at least one of the four corner portions of the light-emitting region in the top view.

14. The light-emitting module according to claim 1, wherein:
the light source further comprises a plurality of third light-emitting units that are each configured to emit light with a third chromaticity different from the first chromaticity and the second chromaticity,
a color temperature of light with the third chromaticity is in a range between a color temperature of light with the first chromaticity and a color temperature of light with the second chromaticity, and
the color temperature of light with the first chromaticity, the color temperature of light with the second chromaticity, and the color temperature of light with the third chromaticity are in a range of duv+0.0010 to duv+0.015.

15. The light-emitting module according to claim 1, further comprising:
a light-transmissive member comprising a cover portion comprising a light diffusion portion, wherein:
the light diffusion portion covers the light exiting surface of the lens.
